(19) United States
(12) Patent Application Publication
(10) Pub. No.: US 2026/0052854 A1
(43) Pub. Date: Feb. 19, 2026

(54) DISPLAY DEVICE, ELECTRONIC DEVICE INCLUDING THE SAME, AND MANUFACTURING METHOD THEREOF

(71) Applicant: Samsung Display Co., Ltd., Yongin-si (KR)

(72) Inventors: Hyun Ho KIM, Yongin-si (KR); Dong Uk KIM, Yongin-si (KR); Hoon Gi LEE, Yongin-si (KR)

(21) Appl. No.: 19/231,825

(22) Filed: Jun. 9, 2025

(30) Foreign Application Priority Data
Aug. 14, 2024 (KR) 10-2024-0108694

(51) Int. Cl. H10K 59/124; H10K 59/122

(52) U.S. Cl. CPC H10K 59/124; H10K 59/122

(57) ABSTRACT

A display device, an electronic device including the display device, and a method of manufacturing the display device are disclosed. The display device may include a substrate, a thin film transistor layer on one surface of the substrate, a planarization film on the thin film transistor and including a first flat portion and a second flat portion that are spaced and/or apart (e.g., spaced apart or separated) from each other and a first inclined portion between the first flat portion and the second flat portion, a pixel electrode on the first flat portion, the first inclined portion, and the second flat portion of the planarization film, a pixel defining film including an opening that exposes a portion of the pixel electrode, a light emitting layer on the pixel electrode in the opening, and a common electrode on the light emitting layer and the pixel defining film.

### CROSS-REFERENCE TO RELATED APPLICATION

The present application claims priority to and the benefit of Korean Patent Application No. 10-2024-0108694, filed on Aug. 14, 2024, in the Korean Intellectual Property Office, the entire content of which is incorporated herein by reference.

### BACKGROUND

### 1. Field

One or more embodiments of the present disclosure relate to a display device, an electronic device including the display device, and a manufacturing method of the display device (or a method of manufacturing the display device).

### 2. Description of the Related Art

With the development of communication technology and media, display devices are being used to display images in one or more suitable places and environments. For example, one or more suitable types (kinds) of display devices, such as liquid crystal displays (LCDs) and/or an organic light emitting diode (OLED) displays, are widely used.

The organic light emitting diode displays are widely used in display devices because they offer fast response times, high luminance, wide luminance angles, wide viewing angles, and operate with low power consumption. However, the luminance of the display devices may be lower when viewing the display devices from a side than compared to viewing them from the front. Also, due to differences in refractive index depending on the color displayed, the color on the display may appear more distorted when viewed the from the side than from the front. As a result, even if the display devices display a white image, a phenomenon in which the image on the display devices appears somewhat or substantially blue when viewed from the side compared to the front.

### SUMMARY

One or more aspects of embodiments of the present disclosure are directed toward a display device with improved (enhanced) luminance and color deviation when viewed from side compared to the front.

One or more aspects of embodiments of the present disclosure are directed toward a manufacturing method of a display device (or a method of manufacturing a display device) with improved (enhanced) luminance and color deviation when viewed from side compared to the front.

Additional aspects of embodiments will be set forth in part in the description which follows and, in part, will be apparent from the description or may be learned by practice of the presented embodiments of the disclosure.

According to one or more embodiments of the present disclosure, a display device may include a substrate, a thin film transistor layer on one surface of the substrate, a planarization film on the thin film transistor and including a first flat portion and a second flat portion that are spaced and/or apart (e.g., spaced apart or separated) from each other and a first inclined portion between the first flat portion and the second flat portion, a pixel electrode on the first flat portion, the first inclined portion, and the second flat portion of the planarization film, a pixel defining film including an opening that exposes a portion of the pixel electrode, a light emitting layer on the pixel electrode in the opening, and a common electrode on the light emitting layer and the pixel defining film. A minimum thickness of the planarization film in the first flat portion may be smaller than a minimum thickness of the planarization film in the second flat portion, and a thickness of the planarization film in the first inclined portion may decrease from the second flat portion to the first flat portion.

An extension line of an upper surface of the planarization film that extends parallel (e.g., substantially parallel) to one surface of the substrate in the first flat portion may be defined as a first extension line, an extension line of the upper surface of the planarization film that extends parallel (e.g., substantially parallel) to one surface of the substrate in the second flat portion may be defined as a second extension line, a line that connects a first point where the first inclined portion and the first extension line cross (e.g., intersect) and a second point where the first inclined portion and the second extension line cross (e.g., intersect) may be defined as a first inclination line, and an angle between the first extension line and the first inclination line may be about 15° to about 35°.

A maximum length between one end of the second flat portion and the second point may be about 0.5 μm to about 1.5 μm.

A planar area of the first inclined portion may be about 70% to about 80% of a planar area of the opening.

The planarization film may further include a second inclined portion spaced and/or apart (e.g., spaced apart or separated) from the first inclined portion and a third flat portion spaced and/or apart (e.g., spaced apart or separated) from the second flat portion, wherein the second inclined portion is between the second flat portion and the third flat portion.

An extension line of an upper surface of the planarization film that extends parallel (e.g., substantially parallel) to one surface of the substrate in the first flat portion may be defined as a first extension line, an extension line of the upper surface of the planarization film that extends parallel (e.g., substantially parallel) to one surface of the substrate in the second flat portion may be defined as a second extension line, an extension line of the upper surface of the planarization film that extends parallel (e.g., substantially parallel) to one surface of the substrate in the third flat portion may be defined as a third extension line, a line that connects a first point where the first inclined portion and the first extension line cross (e.g., intersect) and a second point where the second inclined portion and the second extension line cross (e.g., intersect) may be defined as a first inclination line, a line that connects the second point and a third point where the second inclined portion and the third extension line cross (e.g., intersect) may be defined as a second inclination line, and a first angle, which is an acute angle between the first extension line and the first inclination line, may be greater than a second angle, which is an acute angle between the second extension line and the second inclination line.

A maximum length of the first flat portion in a first direction may be about 20% to about 40% of a maximum length of the opening in the first direction.

An area of the first inclined portion may be about 10% to about 45% of a planar area of the opening.

A thickness of the first inclined portion may be about 1.0 μm to about 2.5 μm.

A planar area of the second flat portion may be about 10% to about 25% of a planar area of the opening.

A thickness of the second inclined portion may be about 0.4 μm to about 1.5 μm.

The pixel electrode may include a first hole defined by a boundary between the first flat portion and the first inclined portion, and a second hole defined by a boundary between the second flat portion and the second inclined portion.

A size of the second hole may be greater than a size of the first hole, and a size of the opening may be greater than the size of the second hole.

The first hole and the second hole may overlap the opening.

According to one or more embodiments of the present disclosure, a manufacturing method of a display device (or a method of manufacturing a display device) may include forming or providing a thin film transistor on one surface of a substrate, forming or providing (applying) a planarization film including a first flat portion and a second flat portion that are spaced and/or apart (e.g., spaced apart or separated) from each other and a first inclined portion between the first flat portion and the second flat portion, on the thin film transistor, forming or providing a pixel electrode on the first flat portion, the first inclined portion, and the second flat portion of the planarization film, forming or providing a pixel defining layer including an opening that exposes a portion of the pixel electrode on the pixel electrode, forming or providing a light emitting layer on the pixel electrode in the opening, and forming or providing a common electrode on the light emitting layer and the pixel defining film. The forming or providing of the planarization film may include forming or providing a first planarization film, forming or providing a second planarization film having a first hole that overlaps the opening on the first planarization film, and forming or providing a third planarization film on the second planarization film and the first planarization film exposed in the first hole.

The forming or providing of the second planarization film may include exposing the second planarization film at a distance of about 25 μm to about 50 μm from a focus of an exposure device.

According to one or more embodiments of the present disclosure, a manufacturing method of a display device (or a method of manufacturing a display device) may include forming or providing a thin film transistor on one surface of a substrate, forming or providing a planarization film including a first flat portion and a second flat portion that are spaced and/or apart (e.g., spaced apart or separated) from each other and a first inclined portion between the first flat portion and the second flat portion, on the thin film transistor, forming or providing a pixel electrode on the first flat portion, the first inclined portion, and the second flat portion of the planarization film, forming or providing a pixel defining layer including an opening that exposes a portion of the pixel electrode on the pixel electrode, forming or providing a light emitting layer on the pixel electrode in the opening, and forming or providing a common electrode on the light emitting layer and the pixel defining film. The forming or providing of the planarization film may include forming or providing a first planarization film, forming or providing a second planarization film having a first hole that overlaps the opening on the first planarization film, and forming or providing a third planarization film having a second hole that overlaps the opening on the second planarization film and the first planarization film exposed in the first hole.

The forming or providing of the planarization film may further include forming or providing a fourth planarization film on the third planarization film, the second planarization film exposed in the second hole, and the first planarization film exposed in the first hole.

A thickness of the fourth planarization film may be about 0.4 μm to about 1.0 μm.

According to one or more embodiments of the present disclosure, a display device may include a substrate, a thin film transistor layer on one surface of the substrate, a planarization film on the thin film transistor and including an inclined portion and a flat portion, a pixel electrode on the inclined portion and the flat portion of the planarization film, a pixel defining film including an opening that exposes a portion of the pixel electrode, a light emitting layer on the pixel electrode in the opening, and a common electrode on the light emitting layer and the pixel defining film. The inclined portion may overlap a central portion of the pixel electrode, and the flat portion may be around (e.g., surround) the inclined portion.

A thickness of the planarization film may increase from a central portion of the inclined portion to an outer portion of the inclined portion.

A width of the flat portion in a first direction may be about 0.5 μm to about 1.5 μm.

According to one or more embodiments of the present disclosure, an electronic device including a display device may include a substrate, a thin film transistor layer on one surface of the substrate, a planarization film on the thin film transistor and including a first flat portion and a second flat portion that are spaced and/or apart (e.g., spaced apart or separated) from each other and a first inclined portion between the first flat portion and the second flat portion, a pixel electrode on the first flat portion, the first inclined portion, and the second flat portion of the planarization film, a pixel defining film including an opening that exposes a portion of the pixel electrode, a light emitting layer on the pixel electrode in the opening, and a common electrode on the light emitting layer and the pixel defining film. A minimum thickness of the planarization film in the first flat portion may be smaller than a minimum thickness of the planarization film in the second flat portion, and a thickness of the planarization film in the first inclined portion may decrease from the second flat portion to the first flat portion.

According to one or more embodiments of the present disclosure, the inclined portion may be formed or provided in the light emitting area by using the planarization film having the inclined surface formed or provided thereon. For example, the inclination of the inclined portion of the light emitting area may be adjusted by forming or providing a hole in the planarization film and adjusting the thickness of the planarization film. Accordingly, the light output from the flat portion of the light emitting area may be directed toward the front direction of the display device, and the light output from the inclined portion of the light emitting area may be directed toward the side direction of the display device. Through this, the degree or occurrence of luminance reduction and color distortion phenomenon may be reduced compared to the front, if (e.g., when) observing the display device from the side.

According to one or more embodiments of the present disclosure, the inclined portion may be formed or provided on the upper surface of the planarization film by utilizing a mask in which a pattern is formed or provided during exposure of the planarization film. For example, by adjusting the pattern of the mask, the size and inclination of the inclined portion of the upper surface of the planarization film may be adjusted. Accordingly, as the light output from the inclined portion of the light emitting area is directed toward the side direction of the display device, the degree or occurrence of luminance reduction and color distortion phenomenon may be reduced compared to the front, if (e.g., when) observing the display device from the side.

For example, according to one or more embodiments of the present disclosure, a display device and its manufacturing method involve forming an inclined portion in the light emitting area using a planarization film with an inclined surface. The inclination may be adjusted by creating a hole in the film and modifying its thickness. This directs light from the flat portion towards the front and light from the inclined portion towards the side, reducing luminance reduction and color distortion if (e.g., when) viewed from the side.

In one or more embodiments, the inclined portion may be formed or provided on the upper surface of the planarization film by utilizing a patterned mask during exposure. Adjusting the mask pattern allows control over the size and inclination of the inclined portion, further reducing luminance reduction and color distortion if (e.g., when) viewed from the side.

However, aspects and features of embodiments of present disclosure are not restricted to the one set forth herein. The above and other aspects and features of certain embodiments of the present disclosure will become more apparent to one of ordinary skill in the art to which the present disclosure pertains by referencing the detailed description of the present disclosure given.

### BRIEF DESCRIPTION OF THE DRAWINGS

The above and other aspects and features of certain embodiments of the present disclosure will become more apparent and more readily appreciated from the following description of one or more embodiments, taken in conjunction with the accompanying drawings, in which:

FIG. 1 is a perspective view of a display device according to one or more embodiments of the present disclosure;

FIG. 2 is a layout view illustrating area A of FIG. 1 in more detail;

FIG. 3 is an enlarged layout view illustrating an example of the pixel electrode of the first light emitting area of FIG. 2;

FIG. 4 is a cross-sectional view illustrating a cross section taken along the line P-P′ of FIG. 3;

FIG. 5 is an enlarged cross-sectional view of part B of FIG. 4;

FIG. 6 is a flowchart illustrating a manufacturing method of a display device according to one or more embodiments of the present disclosure;

FIGS. 7-15 are views illustrating in more detail the manufacturing method of the display device of FIG. 6;

FIG. 16 is an enlarged layout view illustrating another example of the pixel electrode of the first light emitting area of FIG. 2;

FIG. 17 is a cross-sectional view illustrating a cross section taken along the line Q-Q′ of FIG. 16;

FIG. 18 is an enlarged cross-sectional view of portion C of FIG. 17;

FIG. 19 is a flowchart illustrating a manufacturing method of a display device according to one or more embodiments of the present disclosure;

FIGS. 20-26 are views illustrating in more detail the manufacturing method of the display device of FIG. 19.

FIG. 27 is an enlarged layout view illustrating another example of the pixel electrode of the first light emitting area of FIG. 2;

FIG. 28 is a cross-sectional view illustrating a cross section taken along the line R-R′ of FIG. 27;

FIG. 29 is an enlarged cross-sectional view of part D of FIG. 28;

FIG. 30 is a flowchart illustrating a manufacturing method of a display device according to one or more embodiments of the present disclosure;

FIG. 31-38 are views illustrating in more detail the manufacturing method of the display device of FIG. 30;

FIG. 39 is a plan view illustrating a slit mask on the second planarization film in the manufacturing method of the display device according to one or more embodiments of the present disclosure;

FIGS. 40 and 41 are cross-sectional views illustrating a manufacturing method of a display device by utilizing the slit mask of FIG. 39;

FIG. 42 is an enlarged layout view illustrating another example of the pixel electrode of the first light emitting area of FIG. 2;

FIG. 43 is a cross-sectional view illustrating a cross section taken along the line S-S′ of FIG. 42;

FIG. 44 is an enlarged cross-sectional view of part E of FIG. 43;

FIG. 45 is a flowchart illustrating a manufacturing method of a display device according to one or more embodiments of the present disclosure;

FIGS. 46-54 are views illustrating in more detail the manufacturing method of the display device of FIG. 45.

### DETAILED DESCRIPTION

The aspects and features of embodiments of the present disclosure and methods of accomplishing the same may be understood more readily by reference to the detailed description of embodiments and the accompanying drawings. Hereinafter, the subject matter of the present disclosure will be described in more detail with reference to the accompanying drawings, in which embodiments of the present disclosure are shown. In this regard, the subject matter of the present disclosure may be embodied in different forms and should not be construed as being limited to one or more embodiments set forth herein. Rather, these embodiments are provided as examples so that the present disclosure will be thorough and complete and will fully convey the aspects and features of the present disclosure to those skilled in the art. Accordingly, processes, elements, and techniques that are not necessary to those having ordinary skill in the art for a complete understanding of the aspects and features of the present disclosure may not be described.

Unless otherwise noted, like reference numerals, characters, and/or one or more (e.g., any suitable) combinations thereof denote like elements throughout the attached drawings and the written description, and duplicative descriptions thereof may not be provided, and thus, descriptions thereof will not be repeated. Further, parts not related to the description of one or more embodiments may not be shown to make the description clear.

In the drawings, the relative sizes of elements, layers, and regions may be exaggerated to effectively or suitably illustrate the technical contents of the present disclosure. Also, cross-hatching and/or shading in the accompanying drawings may be used to clarify boundaries between adjacent elements. As such, neither the presence nor the absence of cross-hatching and/or shading conveys nor indicates any preference or requirement for certain materials, material properties, dimensions, proportions, commonalities between illustrated elements, and/or any other characteristic, attribute, property, and/or the like of the elements, unless specified.

One or more embodiments of the present disclosure are described herein with reference to sectional illustrations that are schematic illustrations of embodiments and/or intermediate structures. As such, variations from the shapes of the illustrations as a result, for example, of manufacturing techniques and/or tolerances, may be expected. Further, specific structural or functional descriptions disclosed herein are just illustrative for the purpose of describing one or more embodiments of the present disclosure. Thus, one or more embodiments disclosed herein should not be construed as being limited to the specific shapes of regions, but should be construed to include deviations in shapes that result from, for instance, manufacturing. As such, the shapes shown in the drawings may not depict the actual shapes of regions of the device, and embodiments of the present disclosure are not limited thereto.

For example, an implanted region illustrated as a rectangle (e.g., a substantially rectangle) may have rounded or curved features and/or a gradient of implant concentration at its edges rather than a binary change from implanted to non-implanted region. Likewise, a buried region formed or provided by implantation may result in an implantation in the region between the buried region and the surface through which the implantation takes place. Thus, the regions illustrated in the drawings are schematic in nature, and their shapes are not intended to illustrate the actual shape of a region of a device and are not intended to be limiting. Also, as those skilled in the art would realize, the present disclosure may be modified in one or more suitable different ways, all without departing from the spirit or scope of the present disclosure.

In the present disclosure, for the purposes of explanation, one or more specific details are set forth to provide a thorough understanding of one or more embodiments. It is apparent, however, that one or more embodiments may be practiced without these specific details or with one or more equivalent arrangements. In other instances, structures and devices that are generally available or generally used are shown in block diagram form to avoid unnecessarily obscuring one or more embodiments.

Spatially relative terms, such as “beneath,” “below,” “lower,” “under,” “above,” “upper,” and/or the like, may be used herein for ease of explanation to describe the relationship of one element or feature to another element(s) or feature(s) as illustrated in the drawings. It will be understood that the spatially relative terms are intended to encompass different orientations of the device in use or in operation, in addition to the orientation depicted in the drawings. For example, if the device in the drawings is turned over, elements described as “below,” “beneath,” or “under” other elements or features may then be oriented “above” the other elements or features. Thus, the example terms “below” and “under” may encompass both (e.g., simultaneously) an orientation of above and below. The device may be otherwise oriented (e.g., rotated 90 degrees or at other orientations), and the spatially relative descriptors used herein should be interpreted accordingly. Similarly, if (e.g., when) a first part is described as being “on” a second part, this indicates that the first part is at an upper side or a lower side of the second part without the limitation to the upper side thereof on the basis of the gravity direction.

Further, in the present disclosure, the phrase “on a plane” or “in a plan view” refers to viewing a target portion from the top, and the phrase “on a cross-section” or “in a cross-sectional view” refers to viewing a cross-section formed by vertically cutting a target portion from the side.

It will be understood that if (e.g., when) an element, a layer, a region, or a component is referred to as being “formed or provided on,” “on,” “connected to,” or “coupled to” another element, layer, region, or component, it may be directly formed or provided on, on, connected to, or coupled to the other element, layer, region, or component, or indirectly formed or provided on, on, connected to, or coupled to the other element, layer, region, or component such that one or more intervening elements, layers, regions, or components may be present therebetween. For example, if (e.g., when) a layer, a region, or a component is referred to as being “electrically connected” or “electrically coupled” to another layer, region, or component, it may be directly electrically connected or coupled to the other layer, region, and/or component or intervening layers, regions, or components may be present therebetween. However, “directly connected/directly coupled” refers to one component directly connecting or coupling another component without an (e.g., any) intermediate component. In one or more embodiments, other expressions describing relationships between components, such as “between,” “immediately between,” “adjacent to,” and “directly adjacent to,” may be construed similarly. In one or more embodiments, it will also be understood that if (e.g., when) an element or a layer is referred to as being “between” two elements or layers, it may be the only element or layer between the two elements or layers, or one or more intervening elements or layers may also be present therebetween.

In the present disclosure, expressions, such as “at least one of,” “one of,” and “selected from among,” if (e.g., when) preceding a list of elements, modify the entire list of elements and do not modify the individual elements of the list. For example, “at least one of X, Y, and Z,” “at least one of X, Y, or Z,” and “at least one selected from among the group consisting of X, Y, and Z” may be construed as X only, Y only, Z only, any combination of two or more of X, Y, and Z, such as, for instance, XYZ, XYY, XZ, YZ, and ZZ, or a (e.g., any suitable) variation thereof. Similarly, the expression, such as “at least one of A and/or B,” may include A, B, or A and B.

As used herein, the term “and/or” includes any and all combinations of one or more of the associated listed items. For example, the expression, such as “A and/or B,” may include A, B, or A and B. Further, the use of “may” if (e.g., when) describing embodiments of the present disclosure refers to “one or more embodiments of the present disclosure.”

It will be understood that, although the terms “first,” “second,” “third,” and/or the like may be used herein to describe one or more suitable elements, components, regions, layers, and/or sections, these elements, components, regions, layers, and/or sections should not be limited by these terms. These terms are used to distinguish one element, component, region, layer, or section from another element, component, region, layer, or section. Thus, a first element, a first component, a first region, a first layer, or a first section described in more detail could be termed a second element, a second component, a second region, a second layer, or a second section without departing from the spirit and scope of the present disclosure.

In the examples, the x-axis, the y-axis, and/or the z-axis are not limited to three axes of a rectangular coordinate system and may be interpreted in a broader sense. For example, the x-axis, the y-axis, and the z-axis may be normal (e.g., perpendicular) to one another or may represent different directions that are not normal (e.g., perpendicular) to one another. Substantially the same applies for a first direction, a second direction, and/or a third direction.

The terminology used herein is for the purpose of describing certain embodiments only and is not intended to be limiting of the present disclosure. As used herein, the singular forms “a” and “an” are intended to include the plural forms as well, unless the context clearly indicates otherwise.

In the present disclosure, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

As used herein, the term “substantially,” “about,” “approximately,” and similar terms are used as terms of approximation and not as terms of degree and are intended to account for the inherent deviations in measured or calculated values that would be recognized by those of ordinary skill in the art. “About” or “approximately,” as used herein, is inclusive of the stated value and refers to being within an acceptable range of deviation for the particular value as determined by one of ordinary skill in the art, considering the measurement in question and the error associated with measurement of the particular quantity (e.g., the limitations of the measurement system). For example, “about” may refer to being within one or more standard deviations, or within ±30%, ±20%, ±10%, or ±5% of the stated value. Further, the use of “may” if (e.g., when) describing one or more embodiments of the present disclosure refers to “one or more embodiments of the present disclosure.”

If (e.g., when) one or more embodiments may be implemented differently, a set or specific process order may be performed differently from the described order.

For example, two consecutively described processes may be performed at substantially the same time or performed in an order opposite to the described order.

Also, any numerical range disclosed and/or recited herein is intended to include all sub-ranges of substantially the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112 (a) and 35 U.S.C. § 132 (a).

The electronic devices, the electric devices, manufacturing devices thereof, and/or any other relevant devices or components according to one or more embodiments of the present disclosure may be implemented by utilizing any suitable hardware, firmware (e.g., an application-specific integrated circuit), software, and/or a (e.g., any suitable) combination of software, firmware, and hardware. For example, the one or more suitable components of these devices may be formed or provided on one integrated circuit (IC) chip or on separate IC chips. Further, the one or more suitable components of these devices may be implemented on a flexible printed circuit film, a tape carrier package (TCP), a printed circuit board (PCB), or formed or provided on one substrate.

Further, the one or more suitable components of these devices may be a process or thread, running on one or more processors, in one or more computing devices, executing computer program instructions, and interacting with other system components to perform the one or more suitable functionalities as described herein. The computer program instructions may be stored in a memory which may be implemented in a computing device by using a standard memory device, such as, for example, a random access memory (RAM). The computer program instructions may also be stored in other non-transitory computer readable media, such as, for example, a CD-ROM, a flash drive, and/or the like. Also, a person of skill in the art should recognize that the functionality of one or more suitable computing devices may be combined or integrated into a single computing device, or the functionality of a particular computing device may be distributed across one or more other computing devices without departing from the spirit and scope of the present disclosure.

In the context of the present application and unless otherwise defined, the terms “use,” “using,” and “used” may be considered synonymous with the terms “utilize,” “utilizing,” and “utilized,” respectively. Further, the use of “may” when describing embodiments of the inventive concept refers to “one or more embodiments of the inventive concept.”

Unless otherwise defined, all terms (including technical and scientific terms) used herein have substantially the same meaning as commonly understood by one of ordinary skill in the art to which the present disclosure belongs. It will be further understood that terms, such as those defined in dictionaries, that are generally available or generally used, should be interpreted as having a meaning that is consistent with their meaning in the context of the relevant art and/or the present specification, and should not be interpreted in an idealized or overly formal sense, unless expressly so defined herein.

Hereinafter, one or more embodiments will be described in more detail with reference to the accompanying drawings.

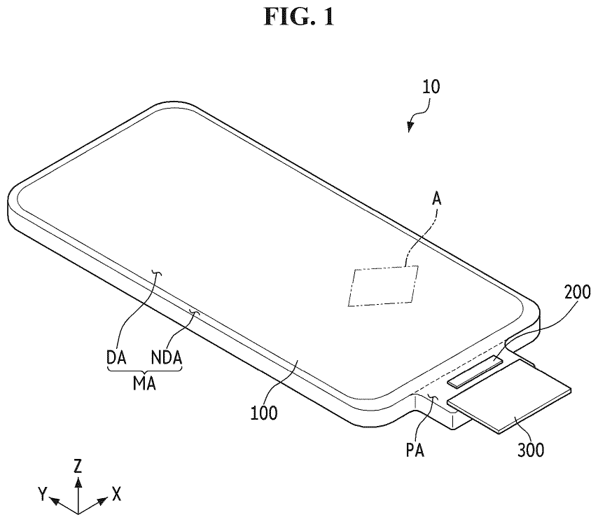

FIG. 1 is a perspective view of a display device according to one or more embodiments of the present disclosure.

Referring to FIG. 1, a display device 10 may be a device to display a still image and/or a moving image and may be used as a display screen of each of one or more suitable products, such as televisions, laptop computers, monitors, billboards, and Internet of Things (IoT), as well as portable electronic devices, such as mobile phones, smartphones, tablet personal computers (PC), smartwatches, watch phones, mobile communication terminals, electronic organizers, electronic books, portable multimedia players (PMPs), navigation devices, and ultra mobile PCs (UMPCs). The display device 10 may be any one selected from among an organic light emitting diode display device, a liquid crystal display device, a plasma display device, a quantum dot light emitting display device, and a micro LED display device. Hereinafter, it is mainly or predominantly described that the display device 10 is the organic light emitting diode display device, but embodiments of the present disclosure are not limited thereto.

The display device 10 may include a display panel 100, a display driving circuit 200, and a circuit board 300.

The display panel 100 may include a main area MA and a protruding area PA that protrudes from one side of the main area MA.

The main area MA may be in a rectangular (e.g., substantially rectangular) plane having short sides in a first direction (X-axis direction) and long sides in a second direction (Y-axis direction) that crosses (e.g., intersects) the first direction (X-axis direction). A corner where the short side in the first direction (X-axis direction) and the long side in the second direction (Y-axis direction) meet each other may be in a round shape (e.g., a substantially round shape) to have a set or predetermined curvature or may be formed or provided at a right angle (e.g., a substantially right angle). The planar shape (e.g., the substantially planar shape) of the display device 10 is not limited to a quadrangular shape (e.g., a substantially quadrangular shape) and may be in other polygonal (e.g., substantially polygonal), circular (e.g., substantially circular), or oval (e.g., substantially oval) shapes.

The main area MA may be formed or provided to be flat (e.g., substantially flat), but embodiments of the present disclosure are not limited thereto and may include curved portions at left end and right end. In this case, the curved portion may have a set or predefined curvature. In one or more embodiments, the main area MA may be formed or provided to be bendable and/or foldable in part or in whole.

The main area MA may include a display area DA in which pixels are formed or provided to display an image and a non-display area NDA around (e.g., surrounding) the display area DA.

In the display area DA, not only the pixels but also the scan lines, the data lines, and the power lines connected to the pixels may be arranged or provided. If (e.g., when) the main area MA includes the curved portion, the display area DA may be on the curved portion. In this case, the image of the display panel 100 may be viewed even on the curved portion.

The non-display area NDA may be defined as an area from the outside of the display area DA to an edge of the display panel 100. A scan driver to apply scan signals to the scan lines and the link lines that connect the data lines and the display driving circuit 200 may be arranged or provided in the non-display area NDA.

The protruding area PA may protrude from one side of the main area MA. For example, the protruding area PA may protrude in an opposite direction of the second direction (Y-axis direction) from the main area MA. A length of the protruding area PA in the first direction (X-axis direction) may be shorter than a length of the main area MA in the first direction (X-axis direction).

The display driving circuit 200 and the circuit board 300 may be in the protruding area PA.

The display driving circuit 200 may be to output signals and voltages to drive the display panel 100. For example, the display driving circuit 200 may be to supply data voltages to the data lines. In one or more embodiments, the display driving circuit 200 may be to supply power voltage to the power line and scan control signals to the scan driver. The display driving circuit 200 may be formed or provided as an integrated circuit (IC) and may be attached onto the display panel 100 in a chip on glass (COG) manner, a chip on plastic (COP) manner, and/or an ultrasonic bonding manner, but embodiments of the present disclosure are not limited thereto. For example, the display driving circuit 200 may be mounted on the circuit board 300.

The circuit board 300 may be attached onto the display panel 100 by utilizing an anisotropic conductive (e.g., electrically conductive) film. Accordingly, the lead lines of the circuit board 300 may be electrically connected to the display panel 100. The circuit board 300 may be a flexible film, such as a flexible printed circuit board, a printed circuit board, or a chip on film.

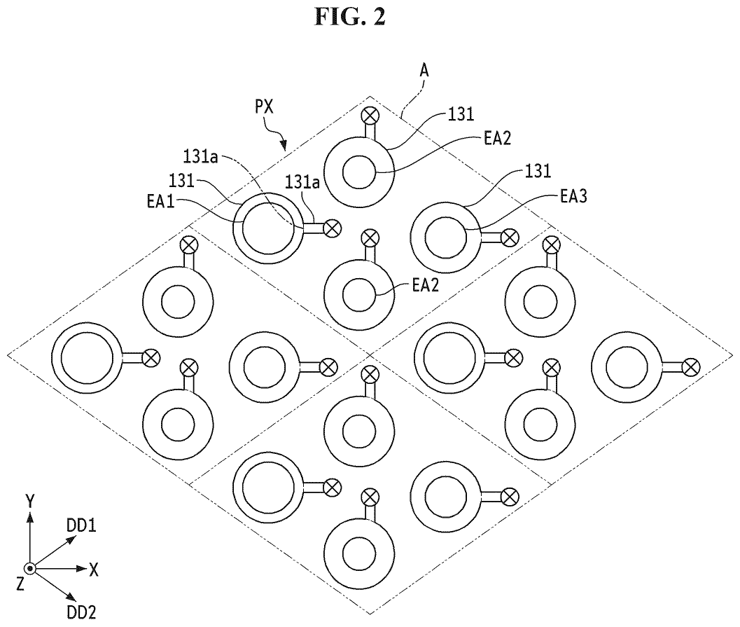

FIG. 2 is a layout view illustrating area A of FIG. 1 in more detail.

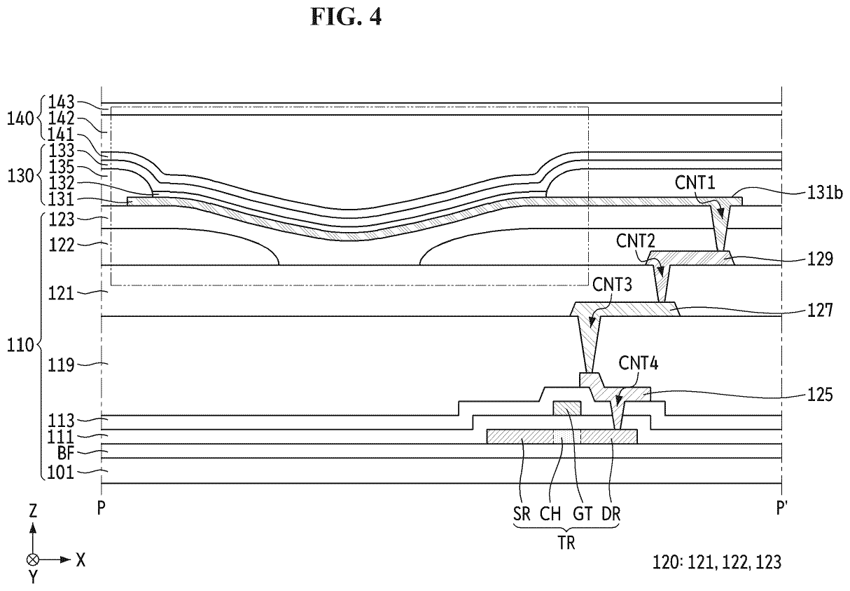

Referring to FIG. 2, the display area DA of the display panel 100 may be defined by a pixel defining film (180 in FIG. 4) and may include a first light emitting area EA1, a second light emitting area EA2, and a third light emitting area EA3 that are light emitting areas that each is to emit a set or predetermined amount of light. Each of the first light emitting area EA1, the second light emitting area EA2, and the third light emitting area EA3 may include a pixel electrode 131, a light emitting layer (132 in FIG. 4), and a common electrode (133 in FIG. 4) and may refer to an area in which the pixel electrode 131, the light emitting layer (132 in FIG. 4), and the common electrode (133 in FIG. 4) are sequentially stacked.

Each of the first light emitting area EA1, the second light emitting area EA2, and the third light emitting area EA3 may have a circular shape (e.g., a substantially circular shape), an elliptical shape (e.g., a substantially elliptical shape), a polygonal shape (e.g., a substantially polygonal shape), or an irregular planar shape (e.g., a substantially irregular planar shape). Hereinafter, a case in which the first light emitting area EA1, the second light emitting area EA2, and the third light emitting area EA3 have a circular shape (e.g., a substantially circular shape) will be described in more detail as an example.

Each of the pixels PX may include one first emitting area EA1, one third emitting area EA3, and two second emitting areas EA2. In this case, in each of the pixels PX, the first light emitting area EA1, the second light emitting area EA2, and the third light emitting area EA3 may be in a diamond shape (e.g., a substantially diamond shape). For example, in each of the pixels PX, the first light emitting area EA1 and the third light emitting area EA3 may be arranged or provided to be adjacent to each other in the first direction (X-axis direction), and the second light emitting areas EA2 may be arranged or provided to be adjacent to each other in the second direction (Y-axis direction).

In one or more embodiments, in each of the pixels PX, the first light emitting area EA1 and one selected from among the second light emitting areas EA2 may be arranged or provided to be adjacent to each other in a first diagonal direction DD1, and the first light emitting area EA1 and the other of the second light emitting area EA2 may be arranged or provided to be adjacent to each other in a second diagonal direction DD2. In one or more embodiments, in each of the pixels PX, one selected from among the second light emitting areas EA2 and the third light emitting area EA3 may be arranged or provided to be adjacent to each other in the second diagonal direction DD2, and the other of the second light emitting areas EA2 and the third light emitting area EA3 may be arranged or provided to be adjacent to each other in the first diagonal direction DD1. The first diagonal direction DD1 may be a direction between the first direction (X-axis direction) and the second direction (Y-axis direction) and may be a direction inclined by 45° with respect to the first direction (X-axis direction) and the second direction (Y-axis direction). The second diagonal direction DD2 may be a direction between the first direction (X-axis direction) and an opposite direction of the second direction (Y-axis direction) and may be a direction inclined by 45° with respect to the first direction (X-axis direction) and the opposite direction of the second direction (Y-axis direction).

For example, in the present disclosure, the pixels may be arranged or provided in a diamond-shaped RGBG (e.g., substantially diamond-shaped RGBG pixels).

The pixel electrode 131 may include a first portion 131a in each of the first light emitting area EA1, the second light emitting area EA2, and the third light emitting area EA3, and a second portion 131b that protrudes in one direction from the first portion 131a. The first portion 131a may have a circular planar shape (e.g., a substantially circular planar shape), but embodiments of the present disclosure are not limited thereto. The second portion 131b may be a portion that protrudes from the first portion 131a. The second portion 131b may be electrically connected to a third connection electrode (129 in FIG. 4) through a first contact hole (CNT1 in FIG. 4).

The second portion 131b of the pixel electrode 131 in the first light emitting area EA1 and the third light emitting area EA3 may protrude in the first direction (X-axis direction) from the first portion 131a. The second portion 131b of the pixel electrode 131 in the second light emitting area EA2 may protrude in the second direction (Y-axis direction) from the first portion 131a.

In one or more embodiments, the first light emitting area EA1 may be to emit first light in a blue wavelength band, the second light emitting area EA2 may be to emit second light in a green wavelength band, and the third light emitting area EA3 may be to emit third light in a red wavelength band. For example, the blue wavelength band may indicate that a main or predominant peak wavelength of light is included in a wavelength band of about 370 nm to about 460 nm, the green wavelength band may indicate that a main or predominant peak wavelength of light is included in a wavelength band of about 480 nm to about 560 nm, and the red wavelength band may indicate that a main or predominant peak wavelength of light is included in a wavelength band of about 600 nm to about 750 nm.

In one or more embodiments, an area of the first light emitting area EA1 may be greater than an area of the third light emitting area EA3, and the area of the third light emitting area EA3 may be greater than an area of the second light emitting area EA2.

For example, a diameter of the first light emitting area EA1 may be about 17 μm to about 19 μm, a diameter of the second light emitting area EA2 may be about 16 μm to about 18 μm, and a diameter of the third light emitting area EA3 may be about 22 μm to about 23 μm.

It is illustrated in FIG. 2 that each of the plurality of pixels PX may include four light emitting areas EA1, EA2, and EA3, but embodiments of the present disclosure are not limited thereto. For example, each of the plurality of pixels PX may also include three light emitting areas.

In one or more embodiments, the arrangement of the light emitting areas EA1, EA2, and EA3 in each of the pixels PX is not limited to that illustrated in FIG. 2. For example, in each of the plurality of pixels PX, the light emitting areas EA1, EA2, and EA3 may be in a stripe structure (e.g., a substantially stripe structure) in which the light emitting areas are in the first direction (X-axis direction), a PENTILE® structure in which the light emitting areas have a diamond arrangement (e.g., a substantially diamond arrangement), or a hexagonal structure (e.g., a substantially hexagonal structure) in which light emitting areas having a hexagonal planar shape (e.g., a substantially hexagonal planar shape) are arranged or provided.

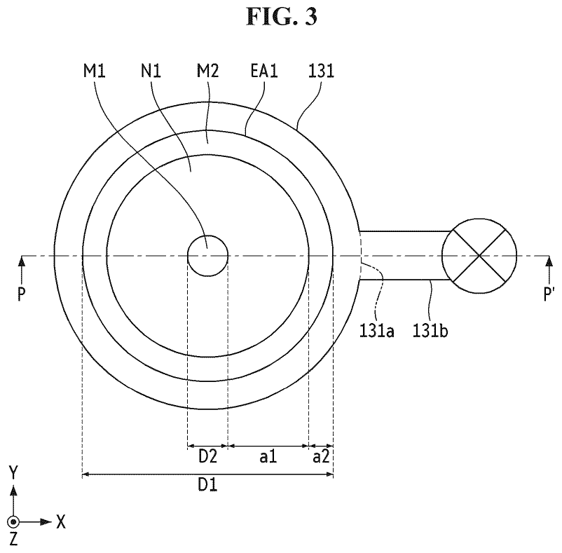

FIG. 3 is an enlarged layout view illustrating an example of the pixel electrode of the first light emitting area of FIG. 2.

The pixel electrode 131 of each of the second light emitting area EA2 and the third light emitting area EA3 may be formed or provided in substantially the same manner as the pixel electrodes 131 in the first light emitting area EA1. Accordingly, a more detailed description of the pixel electrodes 131 in each of the second light emitting area EA2 and the third light emitting area EA3 may not be provided.

Referring to FIG. 3, the first light emitting area EA1 may include a first flat portion M1, a first inclined portion N1, and a second flat portion M2.

The first flat portion M1 may be at a central portion of the first light emitting area EA1. The first flat portion M1 may be an area in which the pixel electrode 131 is flat (e.g., substantially flat) or an inclination of the pixel electrode 131 is less than a first angle. The first angle may be about 3°. For example, the first flat portion M1 may be an area in which the pixel electrode 131 is flat or is close to flat (e.g., substantially flat).

Because the first flat portion M1 is an area in which the pixel electrode 131 is flat or is close to flat (e.g., substantially flat), the first flat portion M1 may be an area in which light generated in the light emitting layer 132 is emitted in a front direction.

A planar shape (e.g., a substantially planar shape) of the first flat portion M1 may follow the planar shape (e.g., the substantially planar shape) of the first light emitting area EA1. If (e.g., when) the first light emitting area EA1 has a circular planar shape (e.g., a substantially circular planar shape) as in FIG. 3, the planar shape (e.g., the substantially planar shape) of the first flat portion M1 may also be circular (e.g., substantially circular).

The first inclined portion N1 may be around (e.g., surround) an outer portion of the first flat portion M1. The first inclined portion N1 may be between the first flat portion M1 and the second flat portion M2.

The first inclined portion N1 may be an area in which the inclination of the pixel electrode 131 is a second angle or more. The second angle may be an angle greater than the first angle. The second angle may be about 15°.

Because the inclination of the second angle or more is formed or provided in the pixel electrode 131, the first inclined portion N1 may be an area in which light generated in the light emitting layer 132 is emitted in a side direction of the display device 10.

The planar shape (e.g., the substantially planar shape) of the first inclined portion N1 may have a round ring shape (e.g., a substantially round ring shape) or a round loop shape (e.g., a substantially round loop shape) having a hollow center, like a donut. A planar area of the first inclined portion N1 may be about 70% to about 80% of a planar area of the first light emitting area EA1.

The second flat portion M2 may be around (e.g., surround) an outer portion of the first inclined portion N1. The second flat portion M2 may be an area in which the pixel electrode 131 is flat (e.g., substantially flat) or the inclination of the pixel electrode 131 is less than the first angle. For example, the second flat portion M2 may be an area in which the pixel electrode 131 is flat or is close to flat (e.g., substantially flat).

Because the second flat portion M2 is an area in which the pixel electrode 131 is flat or is close to flat (e.g., substantially flat), the second flat portion M2 may be an area in which light generated in the light emitting layer 132 is emitted in the front direction.

The planar shape (e.g., the substantially planar shape) of the second flat portion M2 may have a round ring shape (e.g., a substantially round ring shape) or a round loop shape (e.g., a substantially round loop shape) having a hollow center, like a donut. A width a2 of the second flat portion M2 may be smaller than a maximum length D1 of the first light emitting area EA1 in the first direction (X-axis direction). In one or more embodiments, the width a2 of the second flat portion M2 may be smaller than a width a1 of the first inclined portion N1. A minimum value of the width a2 of the second flat portion M2 may be about 0.5 μm.

The first flat portion M1 and the second flat portion M2 may be spaced and/or apart (e.g., spaced apart or separated) from each other, and the first inclined portion N1 may be between the first flat portion M1 and the second flat portion M2.

If (e.g., when) the first flat portion M1 is formed or provided in a circular shape (e.g., a substantially circular shape), a maximum length D2 of the first flat portion M1 in the first direction (X-axis direction) may be equal to a maximum length of the first flat portion M1 in the second direction (Y-axis direction). If (e.g., when) the first inclined portion N1 is formed or provided in a ring shape (e.g., a substantially ring shape), the width a1 of the first inclined portion N1 in the first direction (X-axis direction) may be formed or provided to be substantially the same as the width of the first inclined portion N1 in the second direction (Y-axis direction). If (e.g., when) the second flat portion M2 is formed or provided in a ring shape (e.g., a substantially ring shape), the width a2 of the second flat portion M2 in the first direction (X-axis direction) may be formed or provided to be substantially the same as the width of the second flat portion M2 in the second direction (Y-axis direction).

The maximum length D2 of the first flat portion M1 in the first direction (X-axis direction) may be greater than the width a1 of the first inclined portion N1 in the first direction (X-axis direction). The maximum length of the first flat portion M1 in the second direction (Y-axis direction) may be greater than the maximum length of the first inclined portion N1 in the second direction (Y-axis direction).

The width a1 of the first inclined portion N1 in the first direction (X-axis direction) may be greater than the width a2 of the second flat portion M2 in the first direction (X-axis direction). The maximum length of the first inclined portion N1 in the second direction (Y-axis direction) may be greater than the maximum length of the second flat portion M2 in the second direction (Y-axis direction).

FIG. 4 is a cross-sectional view illustrating a cross section taken along the line P-P′ of FIG. 3.

Referring to FIG. 4, the display panel 100 may include a substrate 101, and a thin film transistor layer 110, a light emitting element layer 130, and a thin film encapsulation layer 140 that are on the substrate 101.

The substrate 101 may be of an insulating (e.g., electrically insulating) material, such as glass, quartz, and/or a polymer resin. In one or more embodiments, the substrate 101 may also include a metal material. The substrate 101 may be a rigid substrate or a flexible substrate that may be bent, folded, and/or rolled. If (e.g., when) the substrate 101 is the flexible substrate, the substrate 101 may be of polyimide PI, but embodiments of the present disclosure are not limited thereto.

The thin film transistor layer 110 may be on the substrate 101. The thin film transistor layer 110 may include thin film transistors TR for each pixel, a first connection electrode 125, a second connection electrode 127, and a plurality of insulating (e.g., electrically insulating) films.

A buffer film BF may be on the substrate 101. The buffer film BF may include a plurality of inorganic films that are alternately stacked. For example, the buffer film BF may be formed or provided as a multi-film (e.g., a multilayer film) in which one or more inorganic films of a silicon nitride layer, a silicon oxynitride layer, a silicon oxide layer, a titanium oxide layer, and/or an aluminum oxide layer are alternately stacked.

An active layer of each of the thin film transistors TR may be on the buffer film BF. The active layer may include a channel CH, a source electrode SR, and a drain electrode DR.

A gate insulating film 111 may be on the active layer. The gate insulating film 111 may be formed or provided as an inorganic insulating (e.g., electrically insulating) film, for example, a silicon nitride (e.g., SiNₓ, wherein 0<x≤2; e.g., Si₃N₄) film, a silicon oxide (e.g., SiOx, wherein 0<X≤2; e.g., SiO₂) film, a silicon nitride oxide film (or a silicon oxynitride (e.g., SiOₓN_{y}, wherein 0<x≤2 and 0≤y≤2; e.g., SiON or Si₂N₂O) film), a titanium oxide (e.g., TiOx, wherein 0<X≤2; e.g., TiO₂) film, and/or an aluminum oxide (e.g., AlOₓ, wherein 0<x≤2; e.g., Al₂O₃) film.

A first gate metal layer may be on the gate insulating film 111. The first gate metal layer may include a gate electrode GT. The gate electrode GT may overlap the channel CH in a third direction (Z-axis direction), which is a thickness direction. The first gate metal layer may be of a single layer or a multi-layer made of any one selected from among molybdenum (Mo), aluminum (Al), chromium (Cr), gold (Au), titanium (Ti), nickel (Ni), neodymium (Nd), and copper (Cu), or an (e.g., any suitable) alloy thereof.

An interlayer insulating film 113 may be on the first gate metal layer. The interlayer insulating film 113 may be formed or provided as an inorganic insulating (e.g., electrically insulating) film, for example, a silicon nitride (e.g., SiNₓ, wherein 0<x≤2; e.g., Si₃N₄) film, a silicon oxide (e.g., SiOₓ, wherein 0<X≤2; e.g., SiO₂) film, a silicon nitride oxide film (or a silicon oxynitride (e.g., SiOₓN_{y}, wherein 0<x≤2 and 0≤ y≤2; e.g., SiON or Si₂N₂O) film), a titanium oxide (e.g., TiOₓ, wherein 0<X≤2; e.g., TiO₂) film, and/or an aluminum oxide (e.g., AlOₓ, wherein 0<x≤2; e.g., Al₂O₃) film.

A first source metal layer may be on the interlayer insulating film 113. The first source metal layer may include a first connection electrode 125. The first connection electrode 125 may be connected to the drain electrode DR of the transistor TR through a fourth contact hole CNT4 that penetrates through the gate insulating film 111 and the interlayer insulating film 113. The first source metal layer may be formed or provided as a single layer or a multi-layer made of any one selected from among molybdenum (Mo), aluminum (Al), chromium (Cr), gold (Au), titanium (Ti), nickel (Ni), neodymium (Nd), and copper (Cu), or an (e.g., any suitable) alloy thereof.

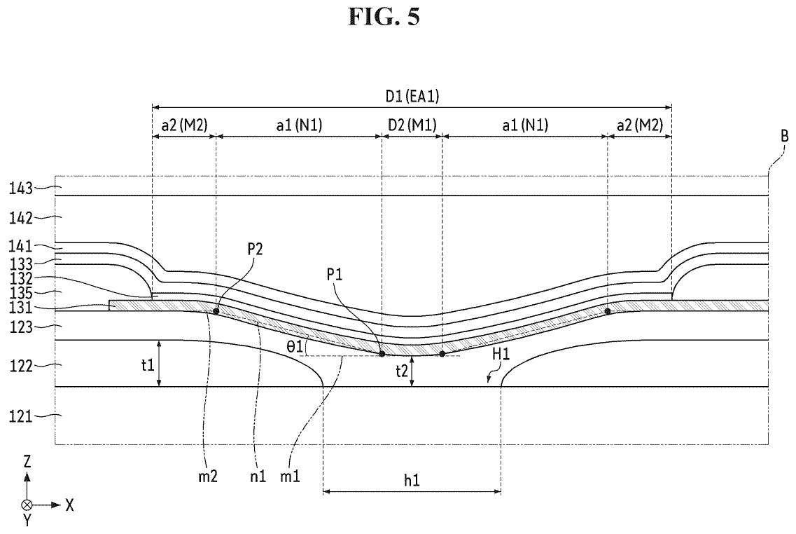

A protective layer 119 may be on the first source metal layer. The protective layer 119 may be formed or provided as an organic insulating (e.g., electrically insulating) film made of an acrylic resin, an epoxy resin, a phenolic resin, a polyamide resin, and/or a polyimide resin. In one or more embodiments, the plurality of insulating (e.g., electrically insulating) films may further include a planarization film 120 on the protective layer 119. The planarization film 120 may include a first planarization film 121, a second planarization film 122, and a third planarization film 123. A more detailed description of the planarization film 120 will be provided herein with reference to FIG. 5.

A second source metal layer may be on the protective layer 119. The second source metal layer may include a second connection electrode 127. The second connection electrode 127 may be connected to the first connection electrode 125 through a third contact hole CNT3 that penetrates through the protective layer 119. The second source metal layer may be formed or provided as a single layer or a multi-layer made of any one selected from among molybdenum (Mo), aluminum (Al), chromium (Cr), gold (Au), titanium (Ti), nickel (Ni), neodymium (Nd), and copper (Cu), or an (e.g., any suitable) alloy thereof.

The first planarization film 121 may be on the second source metal layer. The first planarization film 121 may be formed or provided as an organic insulating (e.g., electrically insulating) film made of an acryl resin, an epoxy resin, a phenolic resin, a polyamide resin, and/or a polyimide resin.

A third source metal layer may be on the first planarization film 121. The third source metal layer may include a third connection electrode 129. The third connection electrode 129 may be connected to the second connection electrode 127 through a second contact hole CNT2 that penetrates through the first planarization film 121. The third source metal layer may be of a single layer or a multi-layer made of any one selected from among molybdenum (Mo), aluminum (Al), chromium (Cr), gold (Au), titanium (Ti), nickel (Ni), neodymium (Nd), and copper (Cu), or an (e.g., any suitable) alloy thereof.

The second planarization film 122 may be on the third source metal layer. The second planarization film 122 may be formed or provided as an organic insulating (e.g., electrically insulating) film made of an acryl resin, an epoxy resin, a phenolic resin, a polyamide resin, and/or a polyimide resin.

The third planarization film 123 may be on the second planarization film 122. The third planarization film 123 may be formed or provided as an organic insulating (e.g., electrically insulating) film made of an acryl resin, an epoxy resin, a phenolic resin, a polyamide resin, and/or a polyimide resin.

The light emitting element layer 130 may be on the planarization film 120. The light emitting element layer 130 may include a pixel electrode 131, a light emitting layer 132, a common electrode 133, and a pixel defining film 135.

For example, a pixel electrode layer may be on the third planarization film 123. The pixel electrode layer may include a pixel electrode 131. The pixel electrode 131 may be connected to the third connection electrode 129 through a first contact hole CNT1 that penetrates through the second planarization film 122 and the third planarization film 123. In a top emission structure that emits light in a direction of the common electrode 133 based on the light emitting layer 132, the pixel electrode 131 may be formed or provided as a single layer made of molybdenum (Mo), titanium (Ti), copper (Cu), aluminum (Al), or an (e.g., any suitable) alloy thereof or be formed or provided in a stacked structure (Ti/Al/Ti) of aluminum and titanium, a stacked structure (ITO/Al/ITO) of aluminum and ITO, an APC alloy, and a stacked structure (ITO/APC/ITO) of an APC alloy and ITO to increase or enhance reflectivity. The APC alloy may be an alloy of silver (Ag), palladium (Pd), and copper (Cu).

The pixel defining film 135 may be on a portion of the pixel electrode 131. The pixel defining film 135 may act or serve to define the light emitting areas EA1, EA2, and EA3 of the pixels. The pixel defining film 135 may be formed or provided to expose a partial area of the pixel electrode 131 on the third planarization film 123. The pixel defining film 135 may cover an edge of the pixel electrode 131. The pixel defining film 135 may be formed or provided as an organic film made of an acryl resin, an epoxy resin, a phenolic resin, a polyamide resin, and/or a polyimide resin.

The light emitting layer 132 may be on the pixel electrode 131. The light emitting layer may be an organic light emitting layer including an organic material. In this case, the light emitting layer may include a hole transporting layer, an organic light emitting layer, and an electron transporting layer. If (e.g., when) a set or predetermined voltage is applied to the pixel electrode and a cathode voltage is applied to the common electrode through the thin film transistor of the thin film transistor layer 110, holes and electrons may move to the organic light emitting layer through the hole transporting layer and the electron transporting layer, respectively, and may be bonded to each other in the organic light emitting layer to emit light. The pixels of the light emitting element layer 130 may be in the display area DA.

The common electrode 133 may be on the pixel defining film 135 and the light emitting layer 132. The common electrode 133 may be formed or provided to cover the light emitting layer 132. The common electrode 133 may be a common layer that is commonly formed or provided in the light emitting areas EA1, EA2, and EA3.

The thin film encapsulation layer 140 may be on the light emitting element layer 130. The thin film encapsulation layer 140 may include a first inorganic encapsulation layer 141 and a second inorganic encapsulation layer 143 that act or serve to prevent oxygen and/or moisture from permeating into the light emitting element layer 130 (or to reduce a degree to or occurrence of which oxygen and/or moisture permeates into the light emitting element layer 130). The first inorganic encapsulation layer 141 and the second inorganic encapsulation layer 143 may be a silicon nitride layer, a silicon oxynitride layer, a silicon oxide layer, a titanium oxide layer, and/or an aluminum oxide layer, but embodiments of the present disclosure are not limited thereto.

In one or more embodiments, the thin film encapsulation layer 140 may include a first organic encapsulation layer 142 that acts or serves to protect the light emitting element layer 130 from foreign substances, such as dust. The first organic encapsulation layer 142 may be between the first inorganic encapsulation layer 141 and the second inorganic encapsulation layer 143. The first organic encapsulation layer 142 may be made of an acrylic resin, an epoxy resin, a phenolic resin, a polyamide resin, and/or a polyimide resin, but embodiments of the present disclosure are not limited thereto.

The thin film encapsulation layer 140 may be in both (e.g., simultaneously) the display area DA and the non-display area NDA. For example, the thin film encapsulation layer 140 may be arranged or provided to cover the light emitting element layer 130 of the display area DA and the non-display area NDA and cover the thin film transistor layer 110 of the non-display area NDA.

FIG. 5 is an enlarged cross-sectional view of part B of FIG. 4.

Referring to FIG. 5, in the first flat portion M1 and the second flat portion M2, an upper surface of the planarization film 120 may be flat (e.g., substantially flat) or an inclination of the upper surface of the planarization film 120 may be less than a first angle. For example, the first angle may be about 3°. If (e.g., when) the inclination of the upper surface of the planarization film 120 is less than about 3°, the upper surface of the planarization film 120 may be seen as almost flat (e.g., substantially flat) without any inclination. The upper surface of the planarization film 120 refers to an upper surface of the third planarization film 123.

In the first inclined portion N1, the inclination of the upper surface of the planarization film 120 may be the first angle or more. If (e.g., when) the inclination of the upper surface of the planarization film 120 is about 3° or more, the upper surface of the planarization film 120 may be seen as having a set or predetermined inclination.

The planarization film 120 may include a first planarization film 121, a second planarization film 122, and a third planarization film 123. The first planarization film 121 may be on the protective layer 119. An upper surface of the first planarization film 121 may be formed or provided to be flat (e.g., substantially flat).

The second planarization film 122 may be on the first planarization film 121. The second planarization film 122 may include a first hole H1 that penetrates through the second planarization film 122. A central portion of the first hole H1 may overlap the first flat portion M1, and an edge portion of the first hole H1 may overlap the first inclined portion N1.

The third planarization film 123 may be on the second planarization film 122. The third planarization film 123 may be on the first planarization film 121 exposed in the first hole H1.

Because the third planarization film 123 includes an organic material and has fluidity before being cured, a second thickness t2 of the third planarization film 123 may have a maximum value in the first hole H1.

An extension line of the upper surface of the third planarization film 123 that extends parallel (e.g., substantially parallel) to one surface of the substrate 101 in the first flat portion M1 may be defined as a first extension line m1. Similarly, an extension line of the upper surface of the third planarization film 123 that extends parallel (e.g., substantially parallel) to one surface of the substrate 101 in the second flat portion M2 may be defined as a second extension line m2. If (e.g., when) a point where the first inclined portion N1 and the first extension line m1 cross (e.g., intersect) is called a first point P1, and a point where the first inclined portion N1 and the second extension line m2 cross (e.g., intersect) is called a second point P2, a line that connects the first point P1 and the second point P2 may be defined as a first inclination line n1. In one or more embodiments, in order for the pixel electrode 131 to have an inclination of the second angle or more in the first inclined portion N1, a first inclination angle θ1 between the first extension line m1 and the first inclination line n1 may be about 15° to about 35°.

If (e.g., when) the first extension line m1 and the first inclination line n1 have the first inclination angle θ1, light emitted from the first inclined portion N1 may travel in the side direction of the display device 10. Therefore, luminance and color difference for each viewing angle of the display panel 100 may be adjusted depending on the first intersecting angle θ1. In one or more embodiments, the luminance for each viewing angle refers to a luminance value according to an angle compared to the front of the display device 10. The color difference for each viewing angle refers to the degree of color distortion according to the angle compared to the front of the display device 10. In this case, the viewing angle is an angle at which a user of the display device views the display device. The viewing angle is 0 degrees if (e.g., when) a viewer views the display device straight on, and the viewing angle may increase as the viewer obliquely views the display device.

If (e.g., when) the first intersecting angle θ1 is less than about 15°, the luminance may decrease if (e.g., when) viewing an image of the display device 10 from the side of the display device 10 compared to if (e.g., when) viewing the image of the display device 10 from the front of the display device 10.

In one or more embodiments, if (e.g., when) the first intersecting angle θ1 is less than about 15°, the upper surface of the pixel electrode 131 may be directed almost toward the upper surface of the display device 10. In a process where light emitted from the light emitting layer 132 passes through a member, such as an encapsulation layer 140, and is refracted, due to a difference in refractive index according to a wavelength of light, long-wavelength light of white light emitted from the display device 10 may be directed in the third direction (Z-axis direction), and short-wavelength light of the white light may be directed in a direction that crosses (e.g., intersects) the third direction (Z-axis direction). Accordingly, a white image of the display device 10 may appear somewhat or substantially blue, if (e.g., when) viewing the white image of the display device 10 in the side of the display device 10 compared to if (e.g., when) viewing the white image of the display device 10 in the front of the display device 10.

If (e.g., when) the first intersecting angle θ1 is between about 15° and about 35°, a long-wavelength portion of light emitted from the first inclined portion N1 may be traveled in a direction that crosses (e.g., intersects) the third direction (Z-axis direction). Accordingly, the phenomenon in which the white image appears somewhat or substantially blue if (e.g., when) viewing the white image of the display device 10 from the side may be reduced.

In contrast, if (e.g., when) the first intersecting angle θ1 exceeds about 35°, a light trap phenomenon in which light is trapped and not emitted between the pixel electrode 131 and the common electrode 133 may occur. In this case, because the generated light may not be emitted, both (e.g., simultaneously) the luminance at the front and the side of the display device may decrease. Accordingly, according to the present disclosure, by forming or providing the first angle θ1 to about 15° to about 35°, the luminance and color difference for each viewing angle may be improved or enhanced if (e.g., when) observing from the side, while minimizing or reducing a decrease in frontal efficiency.

Accordingly, a first thickness t1 of the second planarization film 122 and the second thickness t2 of the third planarization film 123 may be determined in advance (e.g., set or predetermined) as values that may satisfy the range of the first intersecting angle θ1. For example, the first thickness t1 may be formed or provided to be about 1.5 μm to about 3.0 μm, and the second thickness t2 may be formed or provided to be about 0.4 μm to about 1.5 μm. However, the values of the first thickness t1 and the second thickness t2 may vary depending on the maximum length h1 of the first hole H1 in the first direction (X-axis direction) and the maximum length D1 of the first light emitting area EA1 in the first direction (X-axis direction). In the present disclosure, a case in which the maximum length D1 of the first light emitting area EA1 in the first direction (X-axis direction) is about 17 μm to about 19 μm will be described in more detail as an example.

The first planarization film 121, the second planarization film 122, and the third planarization film 123 may be made of substantially the same material. For example, the first planarization film 121, the second planarization film 122, and the third planarization film 123 may be of a photo resist and/or polyimide, but embodiments of the present specification are not limited thereto.

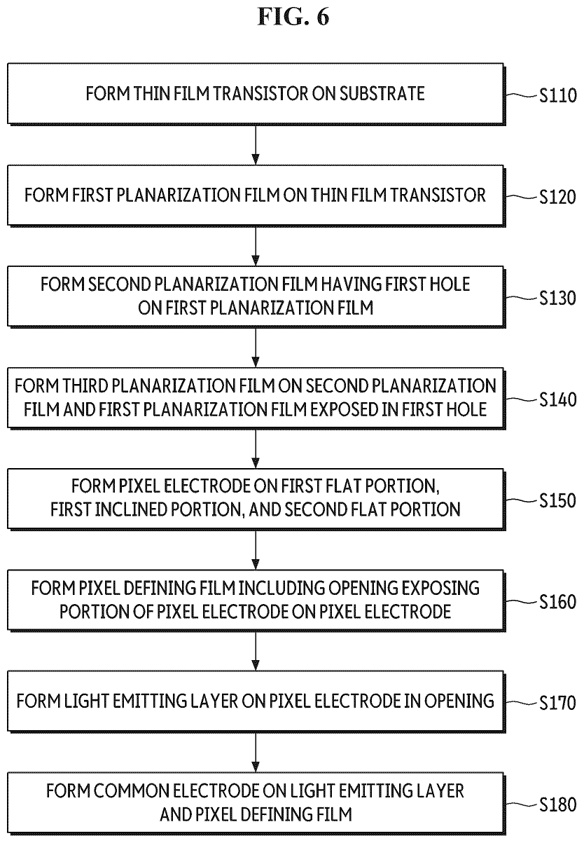

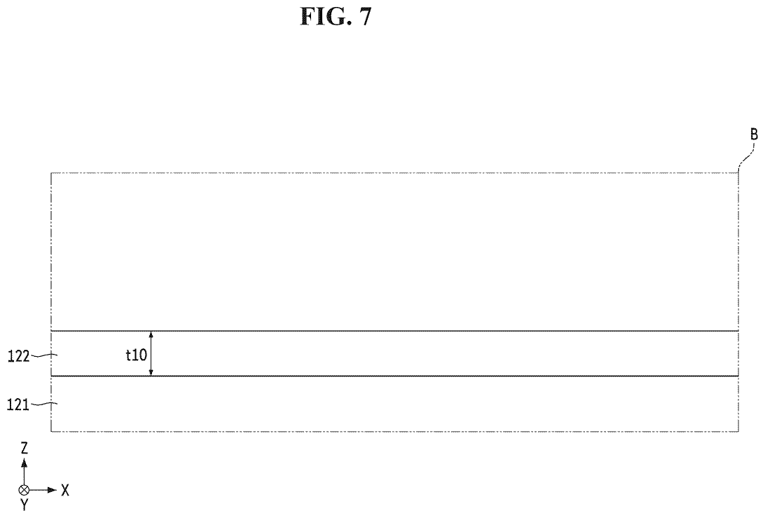

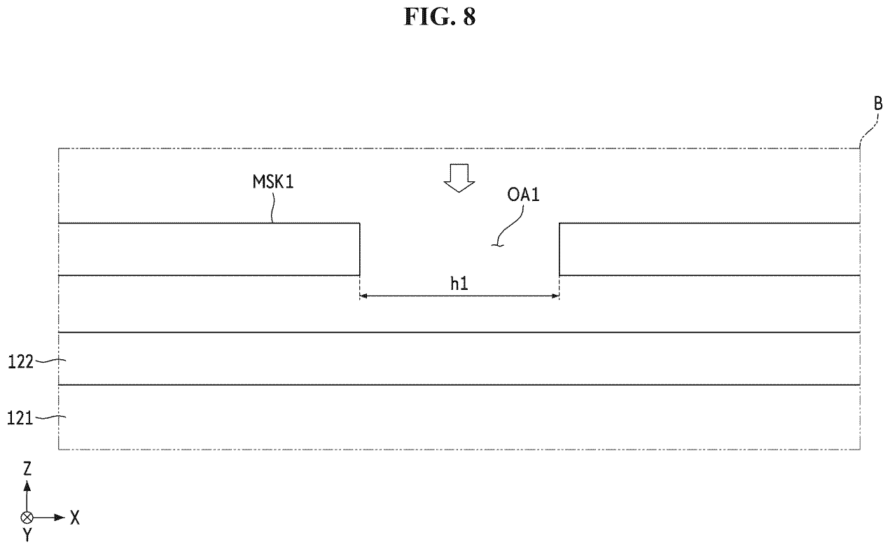

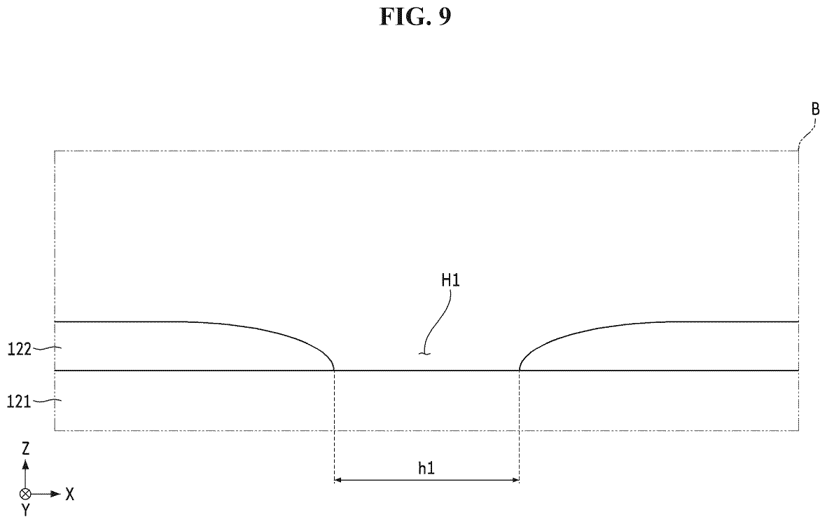

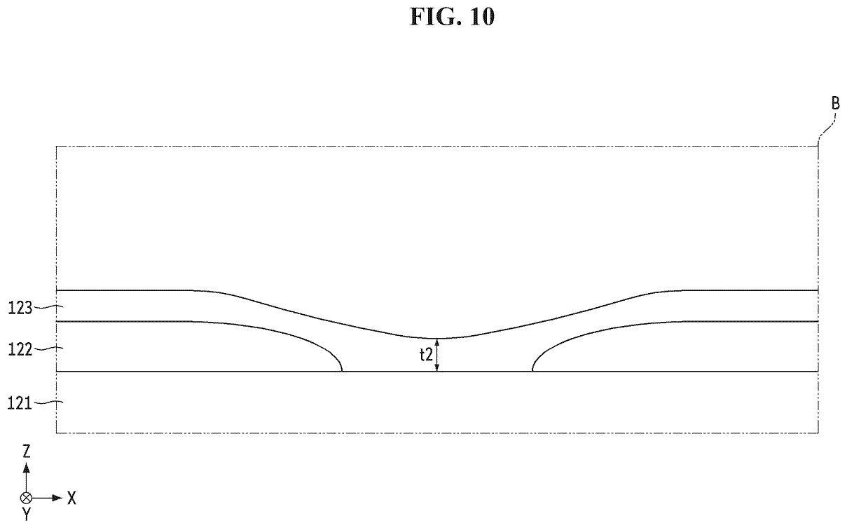

FIG. 6 is a flowchart illustrating a manufacturing method of a display device (or a method of manufacturing a display device) according to one or more embodiments of the present disclosure, and FIGS. 7 to 15 are views illustrating in more detail the manufacturing method of the display device (or the method of manufacturing the display device) of FIG. 6.

Hereinafter, a manufacturing method of a display device (or a method of manufacturing a display device) according to one or more embodiments of the present disclosure will be described in more detail with reference to FIGS. 4 to 15.

First, a plurality of thin film transistors TR may be formed or provided on a substrate 101 (S110 in FIG. 6). Next, a first planarization film 121 may be formed or provided on the thin film transistors TR (S120 in FIG. 6). Next, a second planarization film 122 having a first hole H1 may be formed or provided on the first planarization film 121 (S130 in FIG. 6).

For example, a buffer film BF may be formed or provided on the substrate 101, an active layer may be formed or provided on the substrate 101 by a photolithography process, and a gate insulating film 111 may be formed or provided on the substrate 101 and the active layer. Next, a gate electrode GT may be formed or provided on the gate insulating film 111 by a photolithography process, and an interlayer insulating film 113 may be formed or provided on the gate insulating film 111 and the gate electrode GT.

Next, a first connection electrode 125 that penetrates through the gate insulating film 111 and the interlayer insulating film 113 and connected to the active layer may be formed or provided by a photolithography process, and a protective layer 119 may be formed or provided on the interlayer insulating film 113 and the first connection electrode 125. Next, a second connection electrode 127 may be formed or provided on the protective layer 119 by a photolithography process, and a first planarization film 121 may be formed or provided on the protective layer 119 and the second connection electrode 127.

Next, a third connection electrode 129 may be formed or provided on the first planarization film 121 by a photolithography process, and a second planarization film 122 may be formed or provided on the first planarization film 121 and the third connection electrode 129.

Referring to FIGS. 7 to 9, a second planarization film 122 having a first application thickness t10 may be formed or provided on the first planarization film 121. In one or more embodiments, the first application thickness t10 may be a larger value than the first thickness t1 of FIG. 5. Because the second planarization film 122 is made of an organic material, the thickness of the second planarization film 122 may be reduced by about 50% to about 70% during a process of curing the second planarization film 122. Therefore, the first thickness t1 may have a value that is about 50% to about 70% of the first application thickness t10. For example, the first thickness t1 may be about 2.0 μm to about 3.5 μm. Next, a first hole H1 may be formed or provided by exposing the second planarization film 122 exposed by a first opening OA1 by utilizing a first mask MSK1 having the first opening OA1, and developing the exposed second planarization film 122. In one or more embodiments, because the second planarization film 122 is an organic film, an inclined surface may be around (or surround) the first hole H1 of the second planarization film 122. For example, because the second planarization film 122 includes an organic material, an inclined surface having a continuously (e.g., substantially continuously) changing inclination may be formed or provided around (or surrounding) the first hole H1.

If (e.g., when) performing exposure on the second planarization film 122, a distance between the second planarization film 122 and an exposure device may be spaced and/or apart (e.g., spaced apart or separated) from the focus of light output from the exposure device to expose the second planarization film 122 by about 25 μm to about 50 μm. The range over which the second planarization film 122 is exposed to the light from the exposure device may be increased if (e.g., when) the second planarization film 122 is spaced and/or apart (e.g., spaced apart or separated) from the focus compared to if (e.g., when) the second planarization film 122 is at the focus of the light output from the exposure device. Through this, an area of the inclined surface on the second planarization film 122 may be increased.

Next, a third planarization film 123 may be formed or provided on the second planarization film 122 and the first planarization film 121 exposed in the first hole H1 (S140 in FIG. 6).

Referring to FIGS. 5, 9, and 10, the third planarization film 123 may be formed or provided on the second planarization film 122 and the first planarization film 121 exposed in the first hole H1. For substantially the same reason as the second planarization film 122, an application thickness of the third planarization film 123 may be greater than the second thickness t2. The thickness of the third planarization film 123 may be determined (e.g., set or predetermined) according to the size of the first hole H1. For example, if (e.g., when) the maximum distance h1 of the first hole H1 in the first direction (X-axis direction) is about 30% to about 50% of the maximum distance D1 of an opening H0 in the first direction (X-axis direction), the second thickness t2 of the third planarization film 123 may be about 0.4 μm to about 1.0 μm. As another example, if (e.g., when) the maximum distance h1 of the first hole H1 in the first direction (X-axis direction) is about 50% to about 70% of the maximum distance D1 of the opening H0 in the first direction (X-axis direction), the second thickness t2 of the third planarization film 123 may be about 0.8 μm to about 1.5 μm.

In this case, because the third planarization film 123 is an organic film, the third planarization film 123 may have fluidity before being cured and thus may flow toward the first hole H1. Accordingly, an inclined portion of the third planarization film 123 may be formed or provided to have a gentler inclination than the inclined surface around (e.g., surrounding) the first hole H1 of the second planarization film 122. According to the flow of the third planarization film 123, the maximum length D2 of the first flat portion M1 in the first direction (X-axis direction) may be formed or provided to be smaller than the maximum length h1 of the first hole H1 in the first direction (X-axis direction).

Next, a pixel electrode 131 may be formed or provided on the first flat portion M1, the first inclined portion N1, and the second flat portion M2 (S150 in FIG. 6).

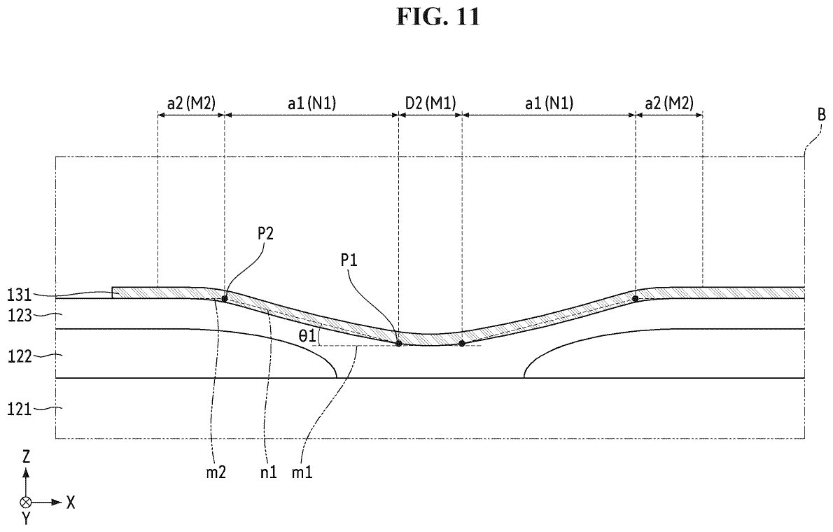

Referring to FIGS. 5 and 11, the pixel electrode 131 may be formed or provided on the third planarization film 123. In this case, one side of the pixel electrode 131 may protrude more than the second flat portion M2 as described in FIG. 5, and the other side of the pixel electrode 131 may extend to the first contact hole CNT1 and be electrically connected to the transistor.

Next, a pixel defining film 135 including an opening that exposes a portion of the pixel electrode 131 may be formed or provided on the pixel electrode 131 (S160 in FIG. 6).

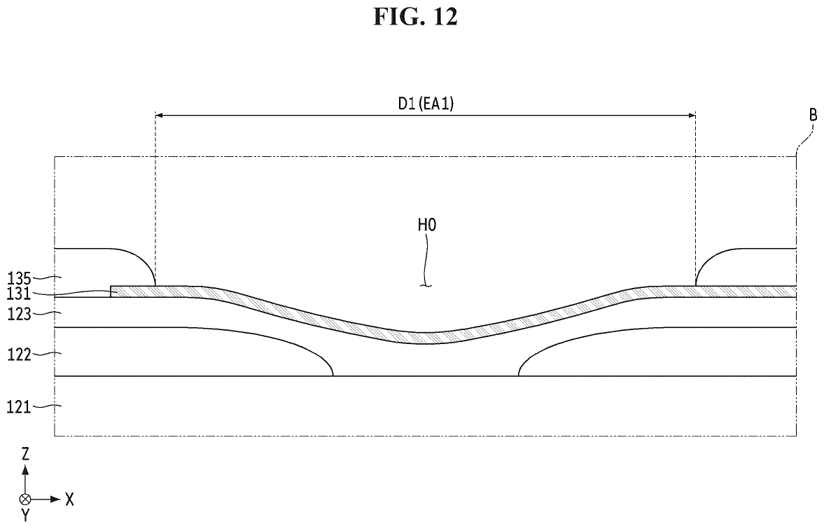

Referring to FIG. 12, a pixel defining film 135 including an opening H0 that exposes a portion of the pixel electrode 131 may be formed or provided on the pixel electrode 131. As the pixel defining film 135 is formed or provided, the second flat portion M2 of the third planarization film 123 may be defined with the interior of the opening H0 as a boundary.

Next, a light emitting layer 132 may be formed or provided on the pixel electrode 131 in the opening H0 (S170 in FIG. 6).

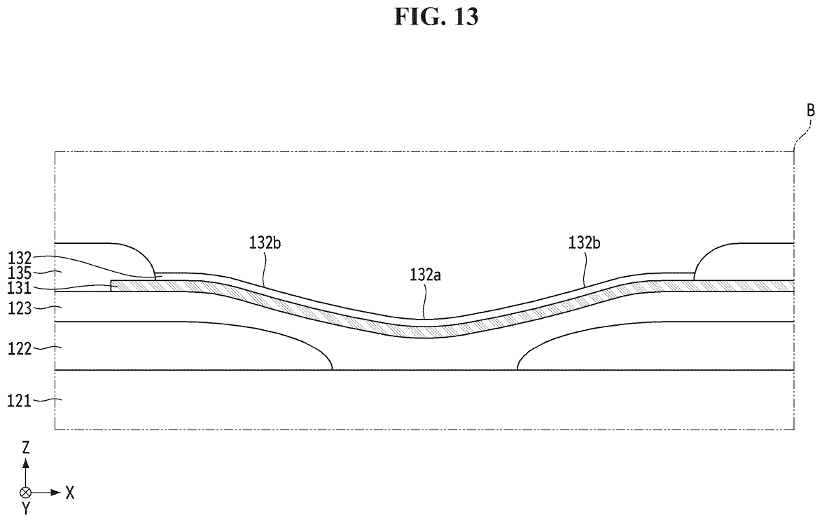

Referring to FIG. 13, a light emitting layer 132 may be formed or provided on the pixel electrode 131 in the opening H0. The light emitting layer 132 may be formed or provided in a curved shape in which a distance from the substrate 101 to a central portion 132a of the light emitting layer 132 is shorter than a distance from the substrate 101 to an edge 132b of the light emitting layer 132 and an inclined surface is formed or provided between the central portion 132a and the edge 132b of the light emitting layer 132 so as to correspond to a shape of the pixel electrode 131.

Next, a common electrode 133 may be formed or provided on the light emitting layer 132 and the pixel defining film 135 (S180 in FIG. 6).

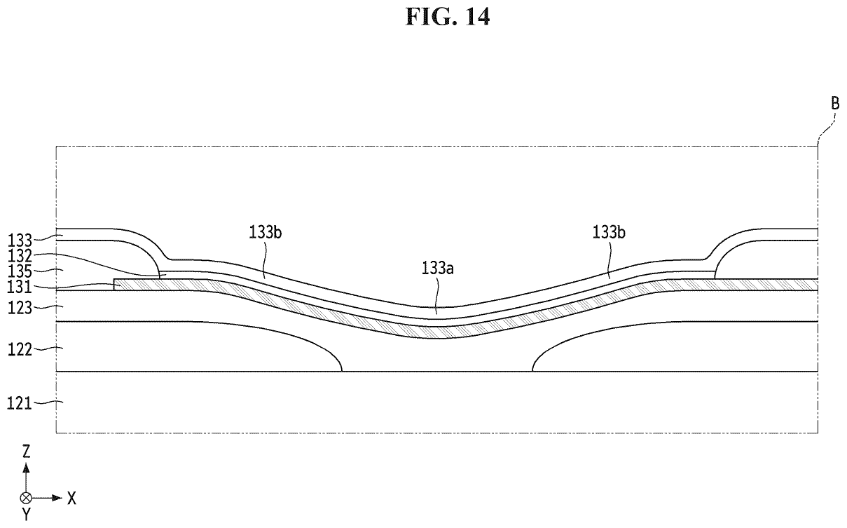

Referring to FIG. 14, a common electrode 133 may be formed or provided on the light emitting layer 132 and the pixel defining film 135. The common electrode 133 may be formed or provided in a curved shape in which a distance from the substrate 101 to a central portion 133a of the common electrode 133 is shorter than a distance from the substrate 101 to an edge 133b of the common electrode 133 and an inclined surface is formed or provided between the central portion 133a and the edge 133b of the common electrode 133 so as to correspond to a shape of the light emitting layer 132.

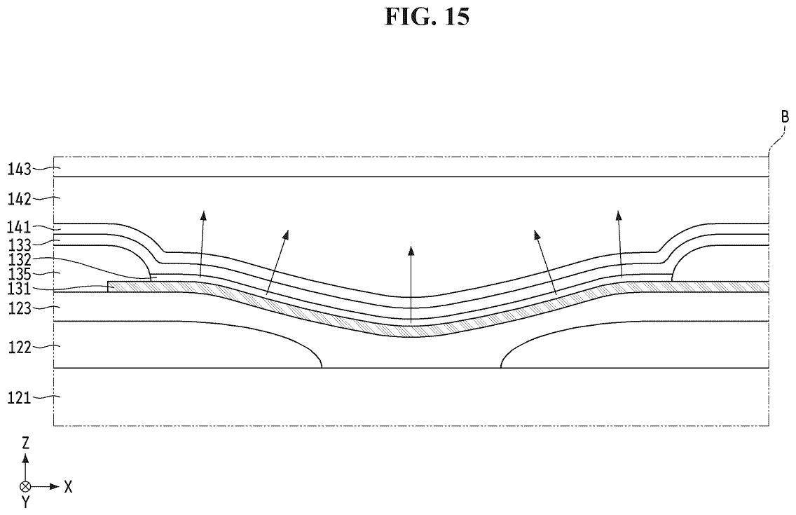

Next, referring to FIG. 15, a first inorganic encapsulation layer 141, a first organic encapsulation layer 142, and a second inorganic encapsulation layer 143 may be sequentially formed or provided on the common electrode 133. The first inorganic encapsulation layer 141 may be formed or provided in a curved shape in which a distance from the substrate 101 to a central portion of the first inorganic encapsulation layer 141 is shorter than a distance from the substrate 101 to an edge of the first inorganic encapsulation layer 141 and an inclined surface is formed or provided between the central portion and the edge of the first inorganic encapsulation layer 141 so as to correspond to a shape of the common electrode 133.

In one or more embodiments, a lower surface of the first organic encapsulation layer 142 may be formed or provided in a curved shape in which a distance from the substrate 101 to a central portion of the lower surface of first organic encapsulation layer 142 is shorter than a distance from the substrate 101 to an edge of the lower surface of the first organic encapsulation layer 142 and an inclination is formed or provided between the central portion and the edge of the lower surface of the first organic encapsulation layer 142 so as to correspond to a shape of the first inorganic encapsulation layer 141. The second inorganic encapsulation layer 143 may be formed or provided in a flat shape (e.g., a substantially flat shape) like the upper surface of the first organic encapsulation layer 142.

The display device manufactured according to the manufacturing method of the display device (or the method of manufacturing the display device) according to one or more embodiments of the present disclosure may be to emit light from both (e.g., simultaneously) the flat portion and the inclined portion of the light emitting layer 132. Accordingly, if (e.g., when) observing the display device from the front, because the long wavelengths emitted from the flat portions M1 and M2 and the short wavelengths emitted from the inclined portion N1 are mixed, the decrease in frontal efficiency may be minimized or reduced. In one or more embodiments, if (e.g., when) observing the display device from the side, because the short wavelengths emitted from the flat portions M1 and M2, the short wavelengths emitted from one inclined portion N1, and long wavelengths emitted from the other inclined portion N1 are mixed, a phenomenon in which color is distorted and a phenomenon in which luminance is reduced if (e.g., when) observed from the side compared to the front may be improved or enhanced.

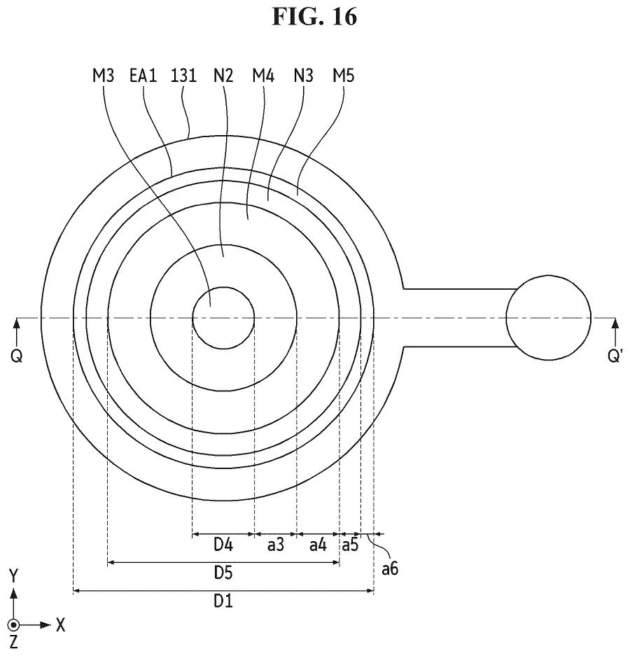

Hereinafter, a display device and a manufacturing method thereof according to one or more embodiments of the present disclosure will be described in more detail with reference to FIGS. 16 to 26. Any contents that overlap one or more embodiments as described herein may not be provided or may be briefly described, and the differences will be mainly or predominantly described.

FIG. 16 is an enlarged layout view illustrating another example of the pixel electrode of the first light emitting area EA1 of FIG. 2.

Referring to FIG. 16, the first light emitting area EA1 may include a third flat portion M3, a second inclined portion N2, a fourth flat portion M4, a third inclined portion N3, and a fifth flat portion M5.

The third flat portion M3 may be at the central portion of the first light emitting area EA1. The third flat portion M3 may be an area in which the pixel electrode 131 is flat (e.g., substantially flat) or the inclination of the pixel electrode 131 is less than a first angle. The first angle may be about 3°. For example, the third flat portion M3 may be an area in which the pixel electrode 131 is flat or is close to flat (e.g., substantially flat). Accordingly, light generated in the light emitting layer 132 of the third flat portion M3 may be emitted in a front direction of the display device 10.

A planar shape (e.g., a substantially planar shape) of the third flat portion M3 may follow the planar shape (e.g., the substantially planar shape) of the first light emitting area EA1. If (e.g., when) the first light emitting area EA1 has a circular planar shape (e.g., a substantially circular planar shape) as in FIG. 16, the planar shape (e.g., the substantially planar shape) of the third flat portion M3 may also be circular (e.g., substantially circular). A maximum length D4 of the third flat portion M3 in the first direction (X-axis direction) may be smaller than the maximum length D1 of the first light emitting area EA1 in the first direction (X-axis direction). For example, the maximum length D4 of the third flat portion M3 in the first direction (X-axis direction) may be about 20% to about 40% of the maximum length D1 of the first light emitting area EA1 in the first direction (X-axis direction).

The second inclined portion N2 may be around (e.g., surround) an outer portion of the third flat portion M3. The second inclined portion N2 may be between the third flat portion M3 and the fourth flat portion M4.

The second inclined portion N2 may be an area in which the inclination of the pixel electrode 131 is a second angle or more. The second angle may be an angle greater than the first angle. The second angle may be about 15°.

Because the inclination of the second angle or more is formed or provided in the pixel electrode 131, the second inclined portion N2 may be an area in which light generated in the light emitting layer 132 is emitted in a side direction of the display device 10.

The planar shape (e.g., the substantially planar shape) of the second inclined portion N2 may have a round ring shape (e.g., a substantially round ring shape) or a round loop shape (e.g., a substantially round loop shape) having a hollow center, like a donut. A width a3 of the second inclined portion N2 may be smaller than the maximum length D1 of the first light emitting area EA1 in the first direction (X-axis direction). A planar area of the second inclined portion N2 may be about 10% to about 45% of a planar area of the first light emitting area EA1.

The fourth flat portion M4 may be around (e.g., surround) an outer portion of the second inclined portion N2. The fourth flat portion M4 may be an area in which the pixel electrode 131 is flat (e.g., substantially flat) or the inclination of the pixel electrode 131 is less than the first angle. For example, the fourth flat portion M4 may be an area in which the pixel electrode 131 is flat or is close to flat (e.g., substantially flat). Accordingly, light generated in the light emitting layer 132 of the fourth flat portion M4 may be emitted in a front direction of the display device 10.

The planar shape (e.g., the substantially planar shape) of the fourth flat portion M4 may have a round ring shape (e.g., a substantially round ring shape) or a round loop shape (e.g., a substantially round loop shape) having a hollow center, like a donut. A width a4 of the fourth flat portion M4 may be smaller than the maximum length D1 of the first light emitting area EA1 in the first direction (X-axis direction). In one or more embodiments, the fourth flat portion M4 may also not be provided.

The third inclined portion N3 may be around (e.g., surround) an outer portion of the fourth flat portion M4. The third inclined portion N3 may be between the fourth flat portion M4 and the fifth flat portion M5.

The third inclined portion N3 may be an area in which the inclination of the pixel electrode 131 is a second angle or more. Accordingly, light generated in the light emitting layer 132 of the third inclined portion N3 may be emitted in a side direction of the display device 10.

The planar shape (e.g., the substantially planar shape) of the third inclined portion N3 may have a round ring shape (e.g., a substantially round ring shape) or a round loop shape (e.g., a substantially round loop shape) having a hollow center, like a donut. A width a5 of the third inclined portion N3 may be smaller than or equal to the width a3 of the second inclined portion N2. A planar area of the third inclined portion N3 may be about 10% to about 25% of a planar area of the first light emitting area EA1.

The fifth flat portion M5 may be around (e.g., surround) an outer portion of the third inclined portion N3. The fifth flat portion M5 may be an area in which the pixel electrode 131 is flat (e.g., substantially flat) or the inclination of the pixel electrode 131 is less than the first angle. Accordingly, light generated in the light emitting layer 132 of the fifth flat portion M5 may be emitted in a front direction of the display device 10.

The planar shape (e.g., the substantially planar shape) of the fifth flat portion M5 may have a round ring shape (e.g., a substantially round ring shape) or a round loop shape (e.g., a substantially round loop shape) having a hollow center, like a donut. A width a6 of the fifth flat portion M5 may be smaller than the maximum length D1 of the first light emitting area EA1 in the first direction (X-axis direction). In one or more embodiments, a minimum value of the width a6 of the fifth flat portion M5 may be about 0.5 μm.

The sum of the planar area of the second inclined portion N2 and the planar area of the third inclined portion N3 may be about 70% to about 80% of the planar area of the first light emitting area EA1.

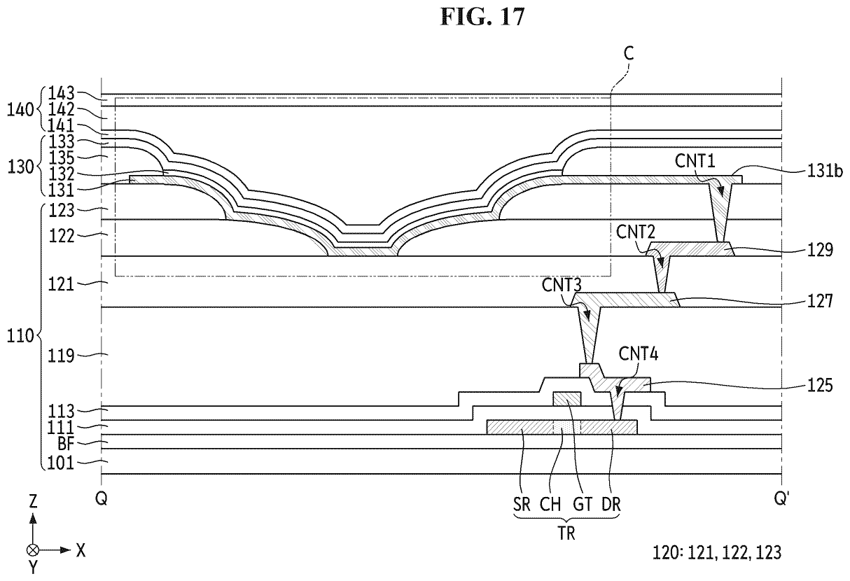

FIG. 17 is a cross-sectional view illustrating a cross section taken along the line Q-Q′ of FIG. 16.

Referring to FIG. 17, the display panel 100 may include a substrate 101, and a thin film transistor layer 110, a light emitting element layer 130, and a thin film encapsulation layer 140 that are on the substrate 101. Among the components, because the remaining portions except for the planarization film 120 of the thin film transistor layer 110 may be formed or provided in substantially the same manner as described in one or more embodiments, a description thereof may not be provided.

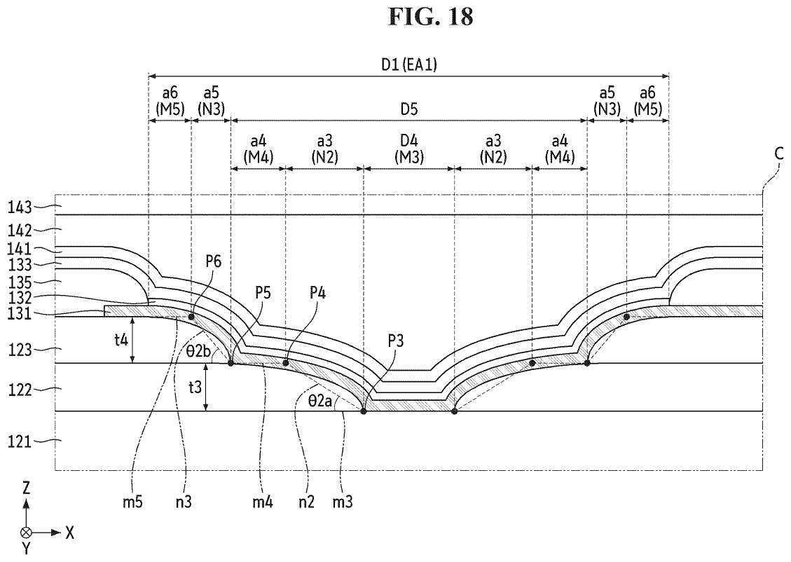

The planarization film 120 may include a first planarization film 121, a second planarization film 122, and a third planarization film 123. In one or more embodiments, the second planarization film 122 may include a second hole (H2 in FIG. 18), and the third planarization film 123 may include a third hole (H3 in FIG. 18). A more detailed description of the planarization film 120 will be provided herein with reference to FIG. 18.

FIG. 18 is an enlarged cross-sectional view of portion C of FIG. 17.

Referring to FIG. 18, in the third flat portion M3, the fourth flat portion M4, and the fifth flat portion M5, an upper surface of the planarization film 120 may be flat (e.g., substantially flat) or an inclination of the upper surface of the planarization film 120 may be less than a first angle. For example, the first angle may be about 3°. If (e.g., when) the inclination of the upper surface of the planarization film 120 is less than about 3°, the upper surface of the planarization film 120 may be seen as almost flat (e.g., substantially flat) without any inclination. The upper surface of the planarization film 120 refers to an upper surface of the third planarization film 123, a portion of an upper surface of the second planarization film 122 that does not overlap the third planarization film 123, and a portion of an upper surface of the first planarization film 121 that does not overlap the second planarization film 122.

In the second inclined portion N2, the inclination of the upper surface of the planarization film 120 may be the first angle or more. If (e.g., when) the inclination of the upper surface of the planarization film 120 is about 3° or more, the upper surface of the planarization film 120 may be seen as having a set or predetermined inclination.

The planarization film 120 may include a first planarization film 121, a second planarization film 122, and a third planarization film 123. The first planarization film 121 may be on the protective layer 119. An upper surface of the first planarization film 121 may be formed or provided to be flat (e.g., substantially flat).

The second planarization film 122 may be on the first planarization film 121. The second planarization film 122 may include a second hole H2 that penetrates through the second planarization film 122. The second hole H2 may overlap the third flat portion M3.

The third planarization film 123 may be on the second planarization film 122. The third planarization film 123 may include a third hole H3 that penetrates through the third planarization film 123. The third hole H3 may overlap the third flat portion M3, the second inclined portion N2, and the fourth flat portion M4.

An extension line of the upper surface of the first planarization film 121 that extends parallel (e.g., substantially parallel) to one surface of the substrate 101 in the third flat portion M3 may be defined as a third extension line m3. Similarly, an extension line of the upper surface of the second planarization film 122 that extends parallel (e.g., substantially parallel) to one surface of the substrate 101 in the fourth flat portion M4 may be defined as a fourth extension line m4. An extension line of the upper surface of the third planarization film 123 that extends parallel (e.g., substantially parallel) to one surface of the substrate 101 in the fifth flat portion M5 may be defined as a fifth extension line m5.

If (e.g., when) a point where the second inclined portion N2 and the third extension line m3 cross (e.g., intersect) is called a third point P3, and a point where the second inclined portion N2 and the fourth extension line m4 cross (e.g., intersect) is called a fourth point P4, a line that connects the third point P3 and the fourth point P4 may be defined as a second inclination line n2. In one or more embodiments, in order for the pixel electrode 131 to have an inclination of the second angle or more in the second inclined portion N2, a second inclination angle θ2a between the third extension line m3 and the second inclination line n2 may be about 15° to about 35°.

Similarly, if (e.g., when) a point where the third inclined portion N3 and the fourth extension line m4 cross (e.g., intersect) is called a fifth point P5, and a point where the third inclined portion N3 and the fifth extension line m5 cross (e.g., intersect) is called a sixth point P6, a line that connects the fifth point P5 and the sixth point P6 may be defined as a third inclination line n3. In one or more embodiments, a third inclination angle θ2b between the fourth extension line m4 and the third inclination line n3 may be about 15° to about 35°.

In one or more embodiments, by forming or providing the inclined surface in two layers, an area of a flat surface (e.g., a substantially flat surface) may be reduced and an area of an inclined surface may be increased at the edge of the first light emitting area EA1. In one or more embodiments, by increasing the area of the inclined surface of the light emitting layer 132, the amount of light emitted from the inclined surface of the light emitting layer 132 and directed toward the side of the display device 10 may be increased. Accordingly, according to the present disclosure, luminance and color difference for each viewing angle if (e.g., when) observing the display device 10 from the side may be improved or enhanced.

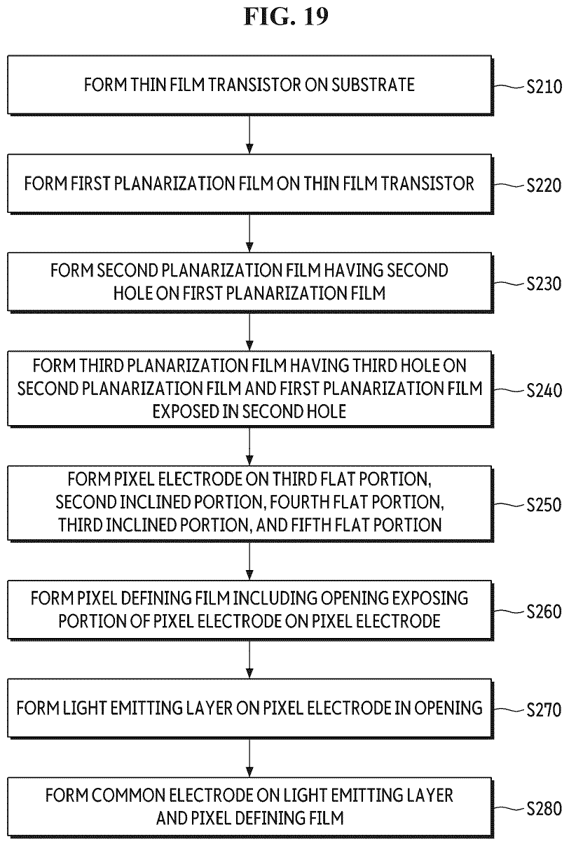

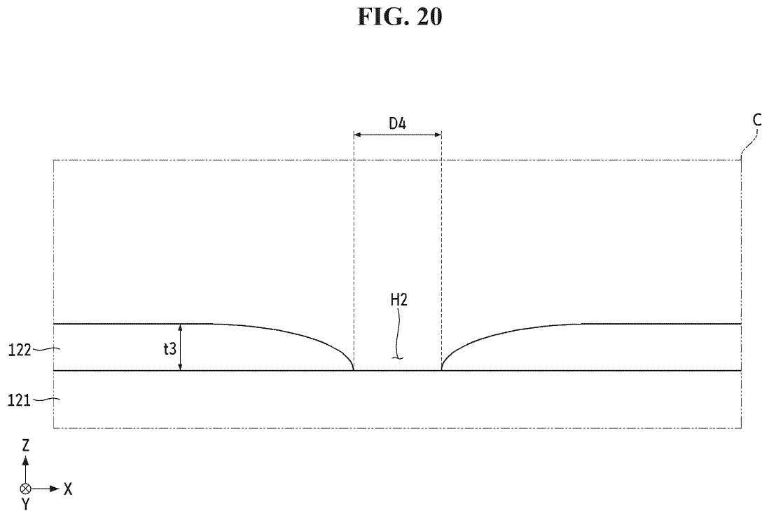

FIG. 19 is a flowchart illustrating a manufacturing method of a display device (or a method of manufacturing a display device) according to one or more embodiments of the present disclosure, and FIGS. 20 to 26 are views illustrating in more detail the manufacturing method of the display device (or the method of manufacturing the display device) of FIG. 19.

Hereinafter, a manufacturing method of a display device (or a method of manufacturing a display device) according to one or more embodiments of the present disclosure will be described in more detail with reference to FIGS. 16 to 26. Any parts that overlap one or more embodiments described herein may not be provided or may be briefly described, and the differences will be mainly or predominantly described.

First, a plurality of thin film transistors TR may be formed or provided on a substrate 101 (S210 in FIG. 19). Next, a first planarization film 121 may be formed or provided on the thin film transistors TR (S220 in FIG. 19). Next, a second planarization film 122 having a second hole H2 may be formed or provided on the first planarization film 121 (S230 in FIG. 19).

Referring to FIG. 20, a second planarization film 122 having a third thickness t3 may be formed or provided on the first planarization film 121. In one or more embodiments, the third thickness t3 may be a thickness after the second planarization film 122 is cured and may be about 1.0 μm to about 2.0 μm. The second hole H2 may be formed or provided by exposing the second planarization film 122 by utilizing a mask having an opening and developing the exposed second planarization film 122.

In this case, a maximum length D4 of the second hole H2 in the first direction (X-axis direction) may vary depending on the opening of the mask. For example, the maximum length D4 of the second hole H2 in the first direction (X-axis direction) may be about 20% to about 40% of the maximum length D1 of the opening H0 in the first direction (X-axis direction).

In one or more embodiments, because the second planarization film 122 is an organic film, an inclined surface having a continuously (e.g., substantially continuously) changing inclination may be formed or provided around (e.g., surrounding) the second hole H2 of the second planarization film 122.

Next, a third planarization film 123 having a third hole H3 may be formed or provided on the second planarization film 122 and the first planarization film 121 exposed in the first hole H1 (S240 in FIG. 19).

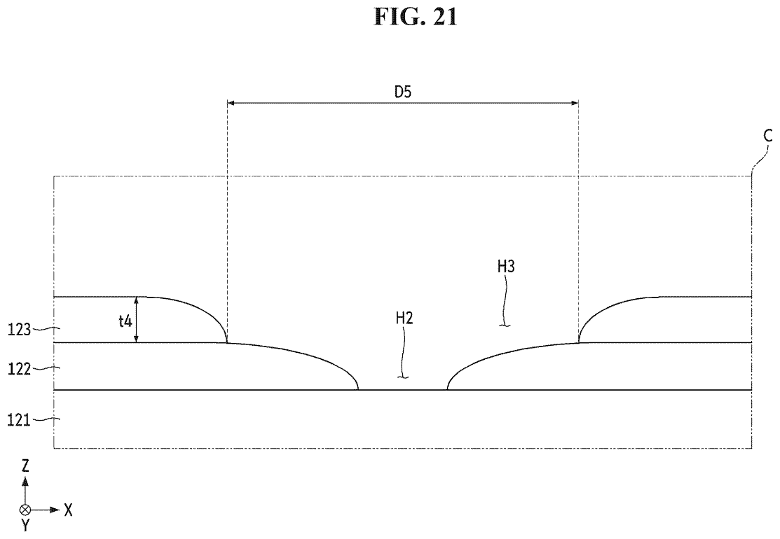

Referring to FIG. 21, a third planarization film 123 having a third hole H3 may be formed or provided on the second planarization film 122 and the first planarization film 121 exposed in the first hole H1. In one or more embodiments, the third planarization film 123 may be formed or provided with a fourth thickness t4. The fourth thickness t4 may be a thickness after the third planarization film 123 is cured and may be about 1.0 μm to about 2.0 μm.

In one or more embodiments, a central portion of the third hole H3 may overlap the second hole H2, and an edge of the third hole H3 may overlap the first planarization film 121. The third hole H3 may be formed or provided by exposing the third planarization film 123 by utilizing a mask having an opening and developing the exposed third planarization film 123. In this case, a maximum length D5 of the third hole H3 in the first direction (X-axis direction) may vary depending on the opening of the mask. For example, the maximum length D5 of the third hole H3 in the first direction (X-axis direction) may be about 50% to about 70% of the maximum length D1 of the first light emitting area EA1 in the first direction (X-axis direction).

In one or more embodiments, because the third planarization film 123 is an organic film, an inclined surface having a continuously (e.g., substantially continuously) changing inclination may be formed or provided around (e.g., surrounding) the third hole H3 of the third planarization film 123.

Next, a pixel electrode 131 may be formed or provided on the third flat portion M3, the second inclined portion N2, the fourth flat portion M4, the third inclined portion N3, and the fifth flat portion M5 (S250 in FIG. 19).

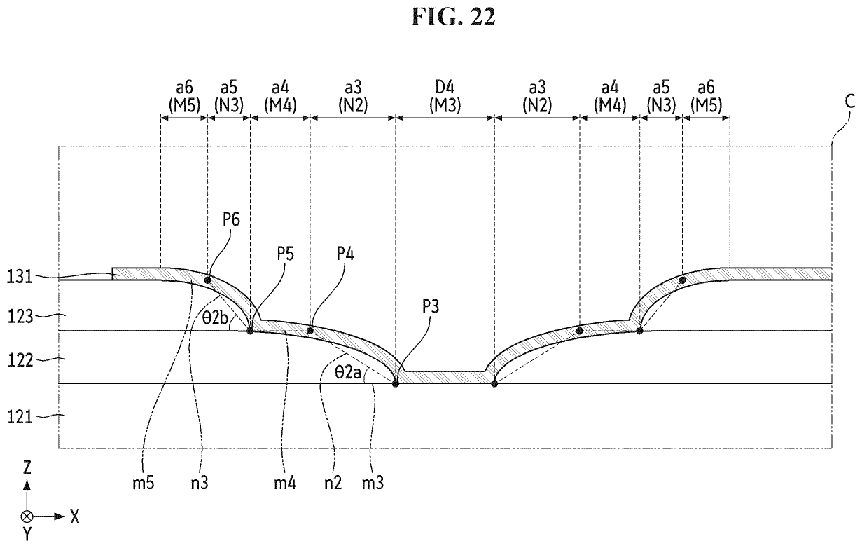

Referring to FIGS. 18 and 22, the pixel electrode 131 may be formed or provided on the third flat portion M3, the second inclined portion N2, the fourth flat portion M4, the third inclined portion N3, and the fifth flat portion M5. In this case, one side of the pixel electrode 131 may protrude more than the fifth flat portion M5 as described in FIG. 18, and the other side of the pixel electrode 131 may extend to the first contact hole CNT1 and be electrically connected to the transistor.

Next, a pixel defining film 135 including an opening H0 that exposes a portion of the pixel electrode 131 may be formed or provided on the pixel electrode 131 (S260 in FIG. 19).

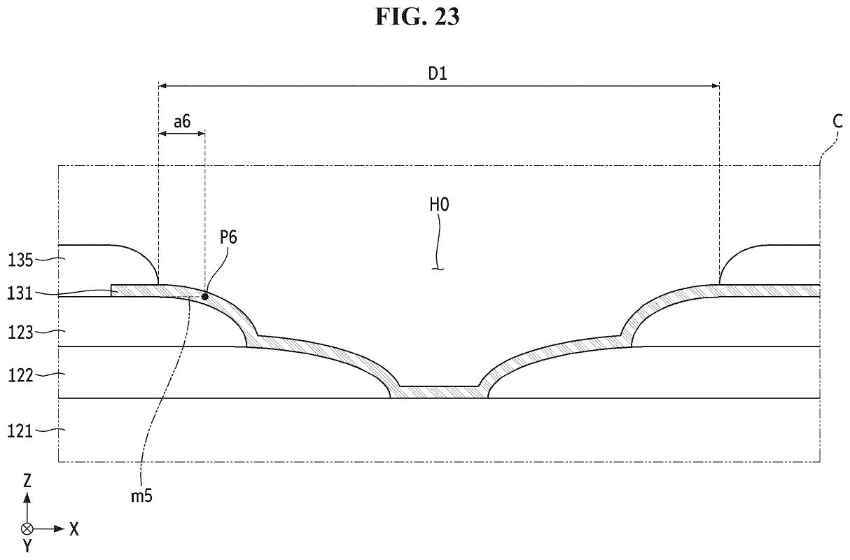

Referring to FIGS. 18 and 23, a pixel defining film 135 including an opening H0 that exposes a portion of the pixel electrode 131 may be formed or provided on the pixel electrode 131. As the pixel defining film 135 is formed or provided, the fifth flat portion M5 of the third planarization film 123 may be defined with the interior of the opening H0 as a boundary.

Next, a light emitting layer 132 may be formed or provided on the pixel electrode 131 in the opening H0 (S270 in FIG. 19).

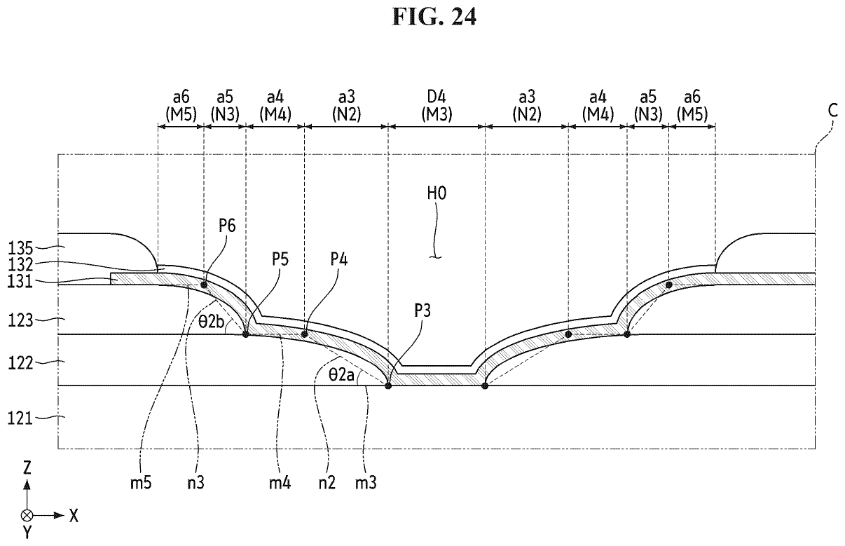

Referring to FIG. 24, a light emitting layer 132 may be formed or provided on the pixel electrode 131 in the opening H0. The light emitting layer 132 may include a third flat portion M3, a second inclined portion N2, a fourth flat portion M4, a third inclined portion N3, and a fifth flat portion M5 so as to correspond to a shape of the pixel electrode 131.

Next, a common electrode 133 may be formed or provided on the light emitting layer 132 and the pixel defining film 135 (S280 in FIG. 19).

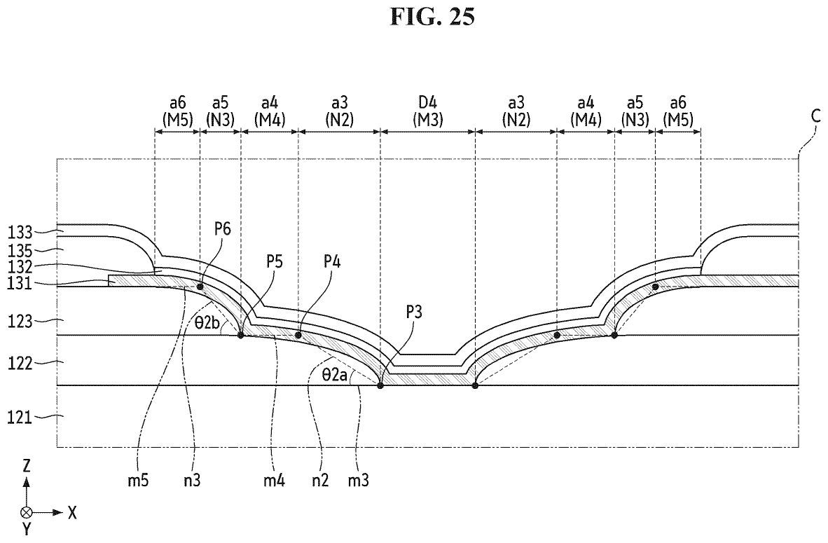

Referring to FIG. 25, a common electrode 133 may be formed or provided on the light emitting layer 132 and the pixel defining film 135. The common electrode 133 may include a third flat portion M3, a second inclined portion N2, a fourth flat portion M4, a third inclined portion N3, and a fifth flat portion M5 so as to correspond to a shape of the light emitting layer 132.

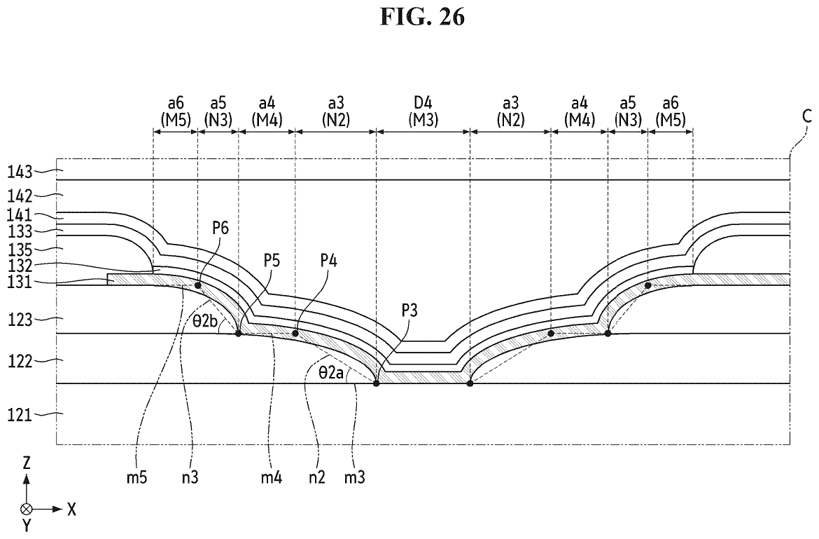

Next, referring to FIG. 26, a first inorganic encapsulation layer 141, a first organic encapsulation layer 142, and a second inorganic encapsulation layer 143 may be sequentially formed or provided on the common electrode 133. The first inorganic encapsulation layer 141 may include a third flat portion M3, a second inclined portion N2, a fourth flat portion M4, a third inclined portion N3, and a fifth flat portion M5 so as to correspond to a shape of the common electrode 133. A lower surface of the first organic encapsulation layer 142 may be formed or provided to correspond to a shape of the first inorganic encapsulation layer 141. In one or more embodiments, an upper surface of the first organic encapsulation layer 142 may be formed or provided in a flat shape (e.g., a substantially flat shape). The second inorganic encapsulation layer 143 may be formed or provided in a flat shape (e.g., a substantially flat shape) like the upper surface of the first organic encapsulation layer 142.

The display device manufactured according to the manufacturing method of the display device (or the method of manufacturing the display device) may form or provide a double inclined surface in the light emitting layer 132 and increase the area of the inclined surface. Through this, the amount of light emitted from the inclined surface of the light emitting layer 132 may be increased, thereby improving or enhancing a luminance ratio at the side compared to the front of the display device 10. In one or more embodiments, if (e.g., when) observing the display device from the side, because the short wavelengths emitted from the flat portions M3, M4, and M5 and the long wavelengths and short wavelengths emitted from the inclined portions N2 and N3 are mixed, a phenomenon in which color is distorted and a phenomenon in which luminance is reduced if (e.g., when) observed from the side compared to the front may be improved or enhanced.

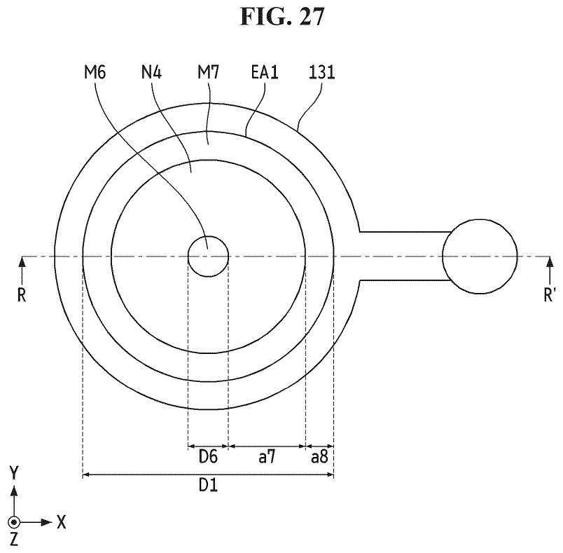

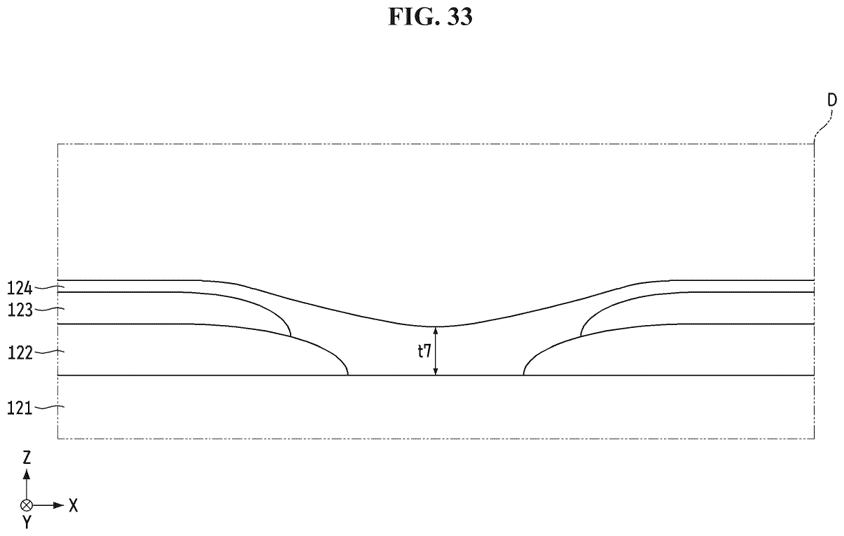

Hereinafter, a display device and a manufacturing method thereof according to one or more embodiments of the present disclosure will be described in more detail with reference to FIGS. 27 to 38. Any contents that overlap one or more embodiments described herein may not be provided or may be briefly described, and the differences will be mainly or predominantly described.

FIG. 27 is an enlarged layout view illustrating another example of the pixel electrode of the first light emitting area EA1 of FIG. 2.

Referring to FIG. 27, the first light emitting area EA1 may include a sixth flat portion M6, a fourth inclined portion N4, and a seventh flat portion M7.

The sixth flat portion M6 may be at a central portion of the first light emitting area EA1. The sixth flat portion M6 may be an area in which the pixel electrode 131 is flat (e.g., substantially flat) or the inclination of the pixel electrode 131 is less than a first angle. The first angle may be about 3°. For example, the sixth flat portion M6 may be an area in which the pixel electrode 131 is flat or is close to flat (e.g., substantially flat). Accordingly, light generated in the light emitting layer 132 of the sixth flat portion M6 may be emitted in a front direction of the display device 10.

A planar shape (e.g., a substantially planar shape) of the sixth flat portion M6 may follow the planar shape (e.g., the substantially planar shape) of the first light emitting area EA1. If (e.g., when) the first light emitting area EA1 has a circular planar shape (e.g., a substantially circular planar shape) as in FIG. 27, the planar shape (e.g., the substantially planar shape) of the sixth flat portion M6 may also be circular (e.g., substantially circular). A maximum length D6 of the sixth flat portion M6 in the first direction (X-axis direction) may be smaller than the maximum length D1 of the first light emitting area EA1 in the first direction (X-axis direction). For example, the maximum length D6 of the sixth flat portion M6 in the first direction (X-axis direction) may be smaller than about 40% of the maximum length D1 of the first light emitting area EA1 in the first direction (X-axis direction).

The fourth inclined portion N4 may be around (e.g., surround) an outer portion of the sixth flat portion M6. The fourth inclined portion N4 may be between the sixth flat portion M6 and the seventh flat portion M7.

The fourth inclined portion N4 may be an area in which the inclination of the pixel electrode 131 is a second angle or more. The second angle may be an angle greater than the first angle. The second angle may be about 15°.

Because the inclination of the second angle or more is formed or provided in the pixel electrode 131, the fourth inclined portion N4 may be an area in which light generated in the light emitting layer 132 is emitted in a side direction of the display device 10.

The planar shape (e.g., the substantially planar shape) of the fourth inclined portion N4 may have a round ring shape (e.g., a substantially round ring shape) or a round loop shape (e.g., a substantially round loop shape) having a hollow center, like a donut. A width a7 of the fourth inclined portion N4 may be smaller than the maximum length D1 of the first light emitting area EA1 in the first direction (X-axis direction). A planar area of the fourth inclined portion N4 may be about 70% to about 80% of a planar area of the first light emitting area EA1.

The seventh flat portion M7 may be around (e.g., surround) an outer portion of the fourth inclined portion N4. The seventh flat portion M7 may be an area in which the pixel electrode 131 is flat (e.g., substantially flat) or the inclination of the pixel electrode 131 is less than the first angle. For example, the seventh flat portion M7 may be an area in which the pixel electrode 131 is flat or is close to flat (e.g., substantially flat). Accordingly, light generated in the light emitting layer 132 of the seventh flat portion M7 may be emitted in a front direction of the display device 10.

The planar shape (e.g., the substantially planar shape) of the seventh flat portion M7 may have a round ring shape (e.g., a substantially round ring shape) or a round loop shape (e.g., a substantially round loop shape) having a hollow center, like a donut. A width a8 of the seventh flat portion M7 may be smaller than the maximum length D1 of the first light emitting area EA1 in the first direction (X-axis direction). In one or more embodiments, a minimum value of the width a8 of the seventh flat portion M7 may be about 0.5 μm.

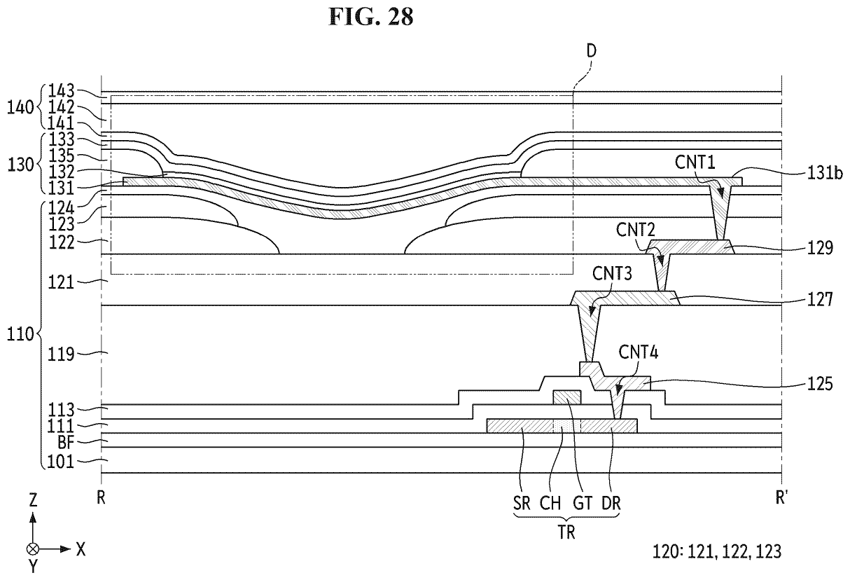

FIG. 28 is a cross-sectional view illustrating a cross section taken along the line R-R′ of FIG. 27.

Referring to FIG. 28, the display panel 100 may include a substrate 101, and a thin film transistor layer 110, a light emitting element layer 130, and a thin film encapsulation layer 140 that are on the substrate 101. Among the components, because the remaining portions except for the planarization film 120 of the thin film transistor layer 110 may be formed or provided in substantially the same manner as described in one or more embodiments, a description thereof may not be provided.

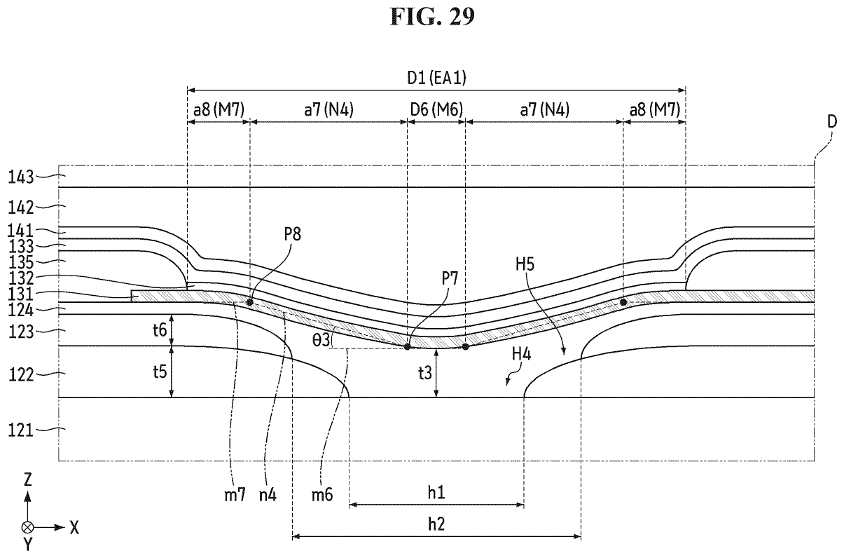

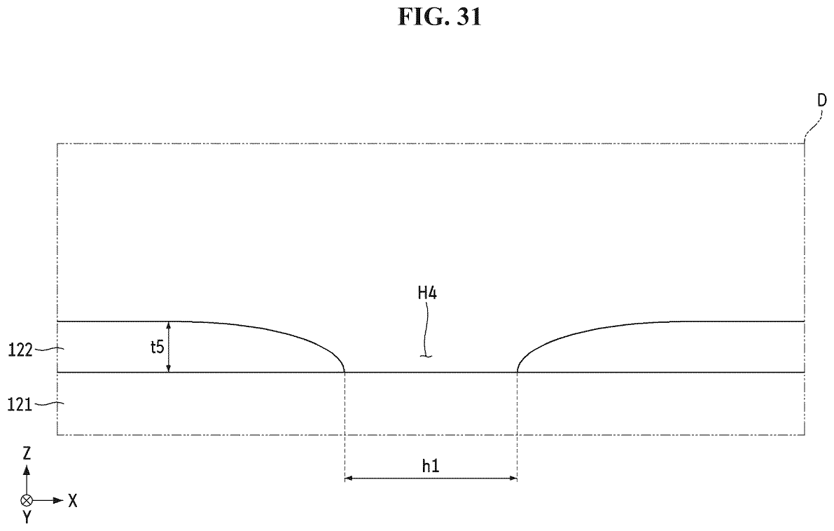

The planarization film 120 may include a first planarization film 121, a second planarization film 122, a third planarization film 123, and a fourth planarization film 124. In one or more embodiments, the second planarization film 122 may include a fourth hole (H4 in FIG. 29), and the third planarization film 123 may include a fifth hole (H5 in FIG. 29). A more detailed description of the planarization film 120 will be provided herein with reference to FIG. 31.

FIG. 29 is an enlarged cross-sectional view of part D of FIG. 28.

Referring to FIG. 29, in the sixth flat portion M6 and the seventh flat portion M7, an upper surface of the planarization film 120 may be flat (e.g., substantially flat) or an inclination of the upper surface of the planarization film 120 may be less than a first angle. For example, the first angle may be about 3°. If (e.g., when) the inclination of the upper surface of the planarization film 120 is less than about 3°, the upper surface of the planarization film 120 may be seen as almost flat (e.g., substantially flat) without any inclination. The upper surface of the planarization film 120 refers to an upper surface of the third planarization film 123, a portion of an upper surface of the second planarization film 122 that does not overlap the third planarization film 123, and a portion of an upper surface of the first planarization film 121 that does not overlap the second planarization film 122.

In the fourth inclined portion N4, the inclination of the upper surface of the planarization film 120 may be the first angle or more. If (e.g., when) the inclination of the upper surface of the planarization film 120 is about 3° or more, the upper surface of the planarization film 120 may be seen as having a set or predetermined inclination.

The planarization film 120 may include a first planarization film 121, a second planarization film 122, a third planarization film 123, and a fourth planarization film 124. The first planarization film 121 may be on the protective layer 119. An upper surface of the first planarization film 121 may be formed or provided to be flat (substantially flat).

The second planarization film 122 may be on the first planarization film 121. The second planarization film 122 may include a fourth hole H4 that penetrates through the second planarization film 122. A central portion of the fourth hole H4 may overlap the sixth flat portion M6, and an edge portion of the fourth hole H4 may overlap the fourth inclined portion N4.

The third planarization film 123 may be on the second planarization film 122. The third planarization film 123 may include a fifth hole H5 that penetrates through the third planarization film 123. A central portion of the fifth hole H5 may overlap the sixth flat portion M6, and an edge portion of the fifth hole H5 may overlap the fourth inclined portion N4.

An extension line of the upper surface of the fourth planarization film 124 that extends parallel (e.g., substantially parallel) to one surface of the substrate 101 in the sixth flat portion M6 may be defined as a sixth extension line m6. Similarly, an extension line of the upper surface of the fourth planarization film 124 that extends parallel (e.g., substantially parallel) to one surface of the substrate 101 in the seventh flat portion M7 may be defined as a seventh extension line m7.

If (e.g., when) a point where the fourth inclined portion N4 and the sixth extension line m6 cross (e.g., intersect) is called a seventh point P7, and a point where the fourth inclined portion N4 and the seventh extension line m7 cross (e.g., intersect) is called an eighth point P8, a line that connects the seventh point P7 and the eighth point P8 may be defined as a fourth inclination line n4. In one or more embodiments, in order for the pixel electrode 131 to have an inclination of the second angle or more in the fourth inclined portion N4, a fourth inclination angle θ3 between the sixth extension line m6 and the fourth inclination line n4 may be about 15° to about 35°.

In one or more embodiments, the area of the inclined surfaces of the light emitting areas EA1, EA2, and EA3 may be increased by using the second planarization film 122 and the third planarization film 123 having the holes H4 and H5 of different sizes. In one or more embodiments, the inclination angle of the inclined surface of the light emitting areas EA1, EA2, and EA3 may be gently or suitably changed by forming or providing the fourth planarization film 124 on the holes H4 and H5. Through this, a phenomenon in which the luminance and color of the observed display device 10 rapidly change depending on the angle if (e.g., when) observing the display device 10 from the side may be prevented or reduced.

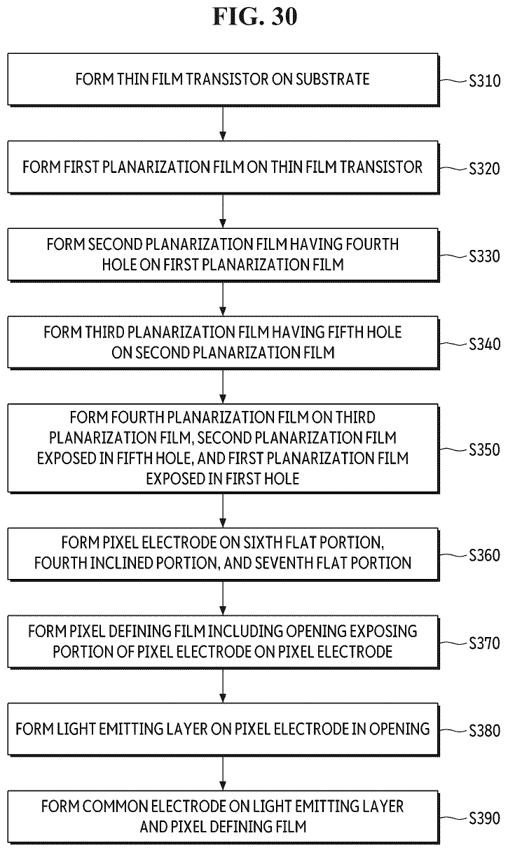

FIG. 30 is a flowchart illustrating a manufacturing method of a display device (or a method of manufacturing a display device) according to one or more embodiments of the present disclosure, and FIGS. 31 to 38 are views illustrating in more detail the manufacturing method of the display device (or the method of manufacturing the display device) of FIG. 30.

Hereinafter, a manufacturing method of a display device (or a method of manufacturing a display device) according to one or more embodiments of the present disclosure will be described in more detail with reference to FIGS. 27 to 38. Any parts that overlap one or more embodiments described herein may not be provided or may be briefly described.

First, a plurality of thin film transistors TR may be formed or provided on a substrate 101 (S310 in FIG. 30). Next, a first planarization film 121 may be formed or provided on the thin film transistors TR (S320 in FIG. 30). Next, a second planarization film 122 having a fourth hole H4 may be formed or provided on the first planarization film 121 (S330 in FIG. 30).

Referring to FIG. 31, a second planarization film 122 having a fifth thickness t5 may be formed or provided on the first planarization film 121. In one or more embodiments, the fifth thickness t5 may be a thickness after the second planarization film 122 is cured and may be about 1.0 μm to about 2.5 μm. The fourth hole H4 may be formed or provided by exposing the second planarization film 122 by utilizing a mask having an opening and developing the exposed second planarization film 122.

In this case, a maximum length h1 of the fourth hole H4 in the first direction (X-axis direction) may vary depending on the mask used during exposure. For example, the maximum length h1 of the fourth hole H4 in the first direction (X-axis direction) may be about 20% to about 40% of the opening H0.

In one or more embodiments, because the second planarization film 122 is an organic film, an inclined surface having a continuously (e.g., substantially continuously) changing inclination may be formed or provided around (e.g., surrounding) the fourth hole H4 of the second planarization film 122.

Next, a third planarization film 123 having a fifth hole H5 may be formed or provided on the second planarization film 122 (S340 in FIG. 30).

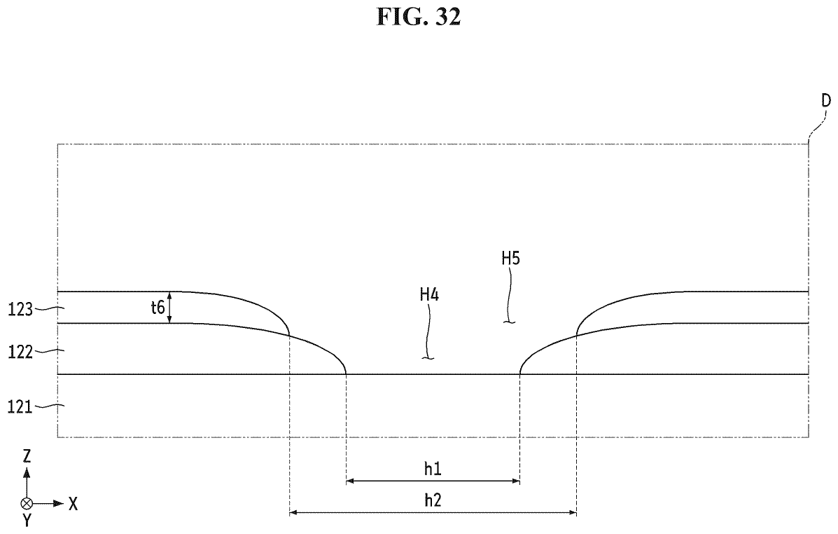

Referring to FIG. 32, a third planarization film 123 having a fifth hole H5 may be formed or provided on the second planarization film 122. In one or more embodiments, the third planarization film 123 may be formed or provided with a sixth thickness t6. The sixth thickness t6 may be a thickness after the third planarization film 123 is cured and may be about 1.0 μm to about 2.5 μm.

In one or more embodiments, a central portion of the fifth hole H5 may overlap the fourth hole H4, and an edge of the fifth hole H5 may overlap the first planarization film 121. A size of the fifth hole H5 may be greater than that of the fourth hole H4. The fifth hole H5 may be formed or provided by exposing the third planarization film 123 by utilizing a mask having an opening and developing the exposed third planarization film 123. In this case, a maximum length h2 of the fifth hole H5 in the first direction (X-axis direction) may be about 50% to about 70% of the maximum length D1 of the first light emitting area EA1 in the first direction (X-axis direction).

In one or more embodiments, because the third planarization film 123 is an organic film, an inclined surface having a continuously (e.g., substantially continuously) changing inclination may be formed or provided around (e.g., surrounding) the fifth hole H5 of the third planarization film 123.

Next, a fourth planarization film 124 may be formed or provided on the third planarization film 123, the second planarization film 122 exposed in the fifth hole H5, and the first planarization film 121 exposed in the fourth hole H4 (S350 in FIG. 30).

Referring to FIGS. 29, 32, and 33, a fourth planarization film 124 may be formed or provided on the third planarization film 123, the second planarization film 122 exposed in the fifth hole H5, and the first planarization film 121 exposed in the fourth hole H4 (S350 in FIG. 30). In this case, because the fourth planarization film 124 is an organic film, the fourth planarization film 124 may have fluidity before being cured and thus may flow toward the fourth hole H4 and the fifth hole H5. Accordingly, an inclined portion of the fourth planarization film 124 may be formed or provided to have a gentler inclination than the inclined surface around (e.g., surrounding) the fourth hole H4 of the second planarization film 122. Similarly, the inclined portion of the fourth planarization film 124 may be formed or provided to have a gentler inclination than the inclined surface around (e.g., surrounding) the fifth hole H5 of the third planarization film 123. According to the flow of the fourth planarization film 124, the maximum length D6 of the sixth flat portion M6 in the first direction (X-axis direction) may be formed or provided to be smaller than the maximum length h1 of the fourth hole H4 in the first direction (X-axis direction).

In one or more embodiments, the fourth planarization film 124 may be formed or provided with a seventh thickness t7. The seventh thickness t7 may be a thickness after the fourth planarization film 124 is cured and may be about 0.4 μm to about 1.0 μm. The seventh thickness t7 may have a maximum value in an area that overlaps the fourth hole H4.

Next, a pixel electrode 131 may be formed or provided on the sixth flat portion M6, the fourth inclined portion N4, and the seventh flat portion M7 (S360 in FIG. 30).

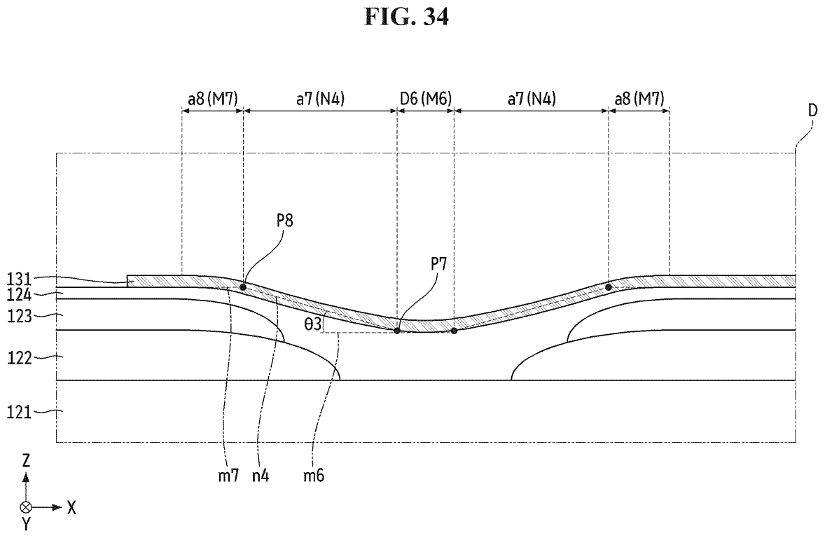

Referring to FIGS. 29 and 34, the pixel electrode 131 may be formed or provided on the sixth flat portion M6, the fourth inclined portion N4, and the seventh flat portion M7. In this case, one side of the pixel electrode 131 may protrude more than the sixth flat portion M6 as described in FIG. 29, and the other side of the pixel electrode 131 may extend to the first contact hole CNT1 and be electrically connected to the transistor.

Next, a pixel defining film 135 including an opening that exposes a portion of the pixel electrode 131 may be formed or provided on the pixel electrode 131 (S370 in FIG. 30).

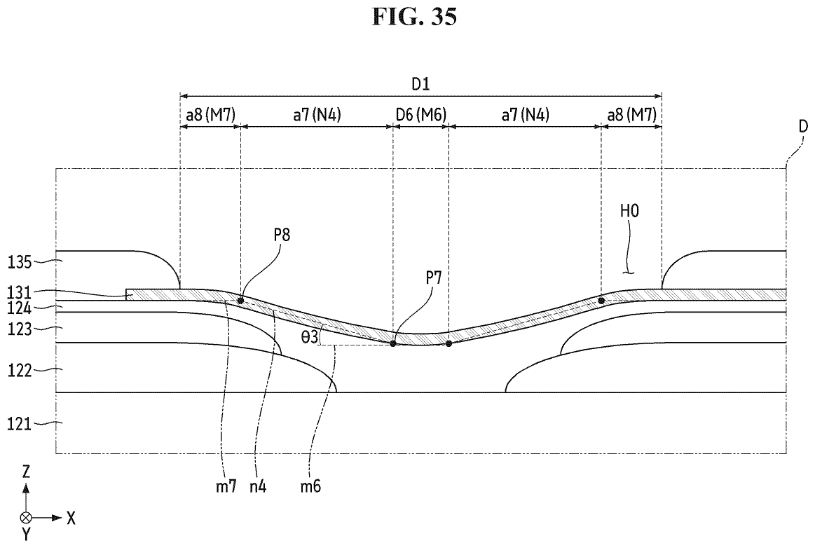

Referring to FIGS. 29 and 35, a pixel defining film 135 including an opening H0 that exposes a portion of the pixel electrode 131 may be formed or provided on the pixel electrode 131. As the pixel defining film 135 is formed or provided, the seventh flat portion M7 of the fourth planarization film 124 may be defined with the interior of the opening H0 as a boundary.

Next, a light emitting layer 132 may be formed or provided on the pixel electrode 131 in the opening H0 (S380 in FIG. 30).

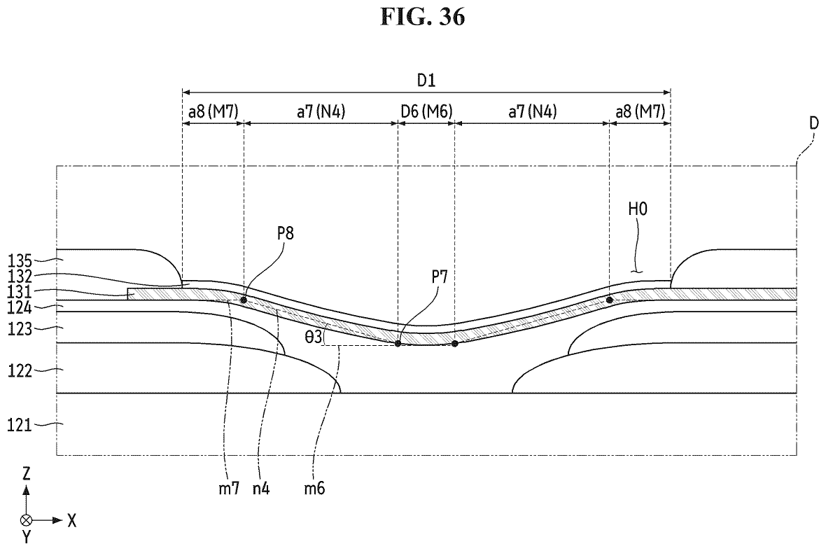

Referring to FIG. 36, a light emitting layer 132 may be formed or provided on the pixel electrode 131 in the opening H0. The light emitting layer 132 may include a sixth flat portion M6, a fourth inclined portion N4, and a seventh flat portion M7 so as to correspond to a shape of the pixel electrode 131.

Next, a common electrode 133 may be formed or provided on the light emitting layer 132 and the pixel defining film 135 (S390 in FIG. 30).

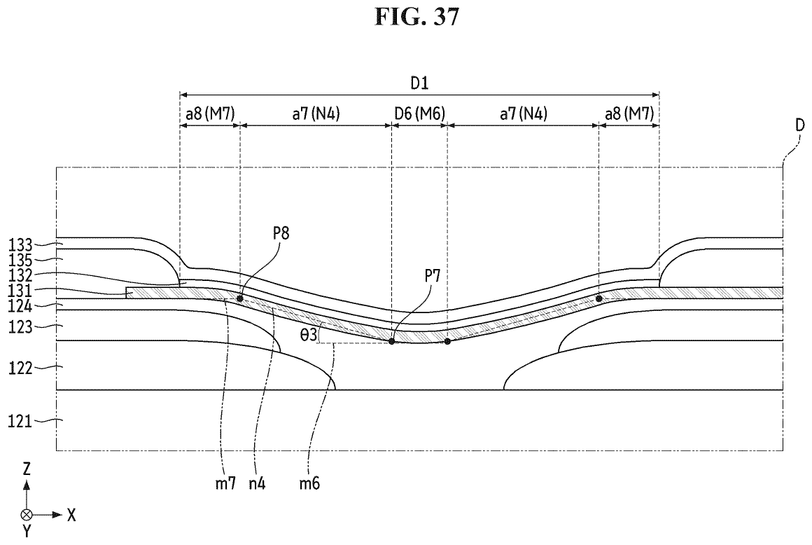

Referring to FIG. 37, a common electrode 133 may be formed or provided on the light emitting layer 132 and the pixel defining film 135. The common electrode 133 may include a sixth flat portion M6, a fourth inclined portion N4, and a seventh flat portion M7 so as to correspond to a shape of the light emitting layer 132.

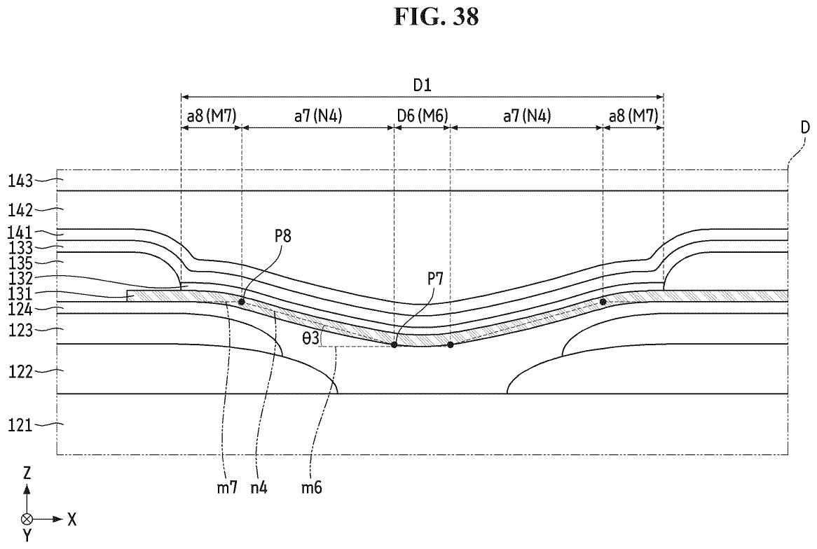

Next, referring to FIG. 38, a first inorganic encapsulation layer 141, a first organic encapsulation layer 142, and a second inorganic encapsulation layer 143 may be sequentially formed or provided on the common electrode 133. The first inorganic encapsulation layer 141 may include a sixth flat portion M6, a fourth inclined portion N4, and a seventh flat portion M7 so as to correspond to a shape of the common electrode 133. A lower surface of the first organic encapsulation layer 142 may be formed or provided to correspond to a shape of the first inorganic encapsulation layer 141. In one or more embodiments, an upper surface of the first organic encapsulation layer 142 may be formed or provided in a flat shape (e.g., a substantially flat shape). The second inorganic encapsulation layer 143 may be formed or provided in a flat shape (e.g., a substantially flat shape) like the upper surface of the first organic encapsulation layer 142.

The display device manufactured according to the manufacturing method of the display device (or the method of manufacturing the display device) according to one or more embodiments of the present disclosure may increase an area of the inclined surface of the light emitting layer 132 by using the second planarization film 122 and the third planarization film 123 having the holes H4 and H5 of different sizes. In one or more embodiments, a rapid change in the inclination angle of the inclined surface of the light emitting layer 132 may be prevented or reduced by forming or providing the fourth planarization film 124 on the holes H4 and H5 and the first planarization film 121, the second planarization film 122, and the third planarization film 123. Through this, a phenomenon in which the luminance and color rapidly change depending on the angle if (e.g., when) observing the display device 10 from the side may be prevented or reduced.

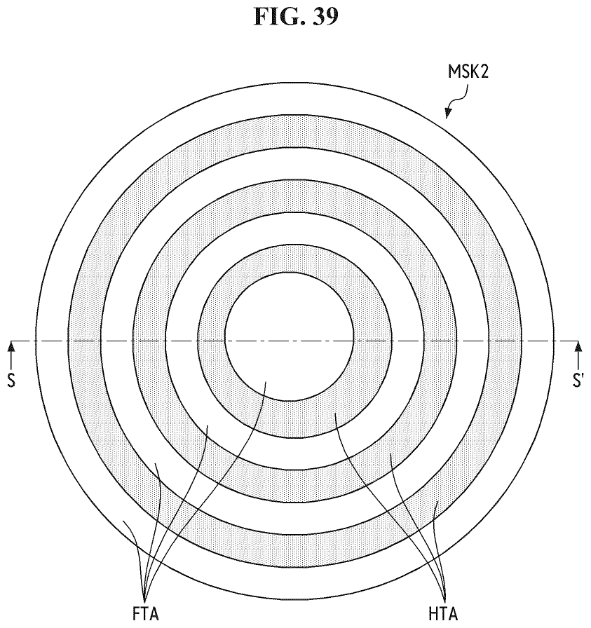

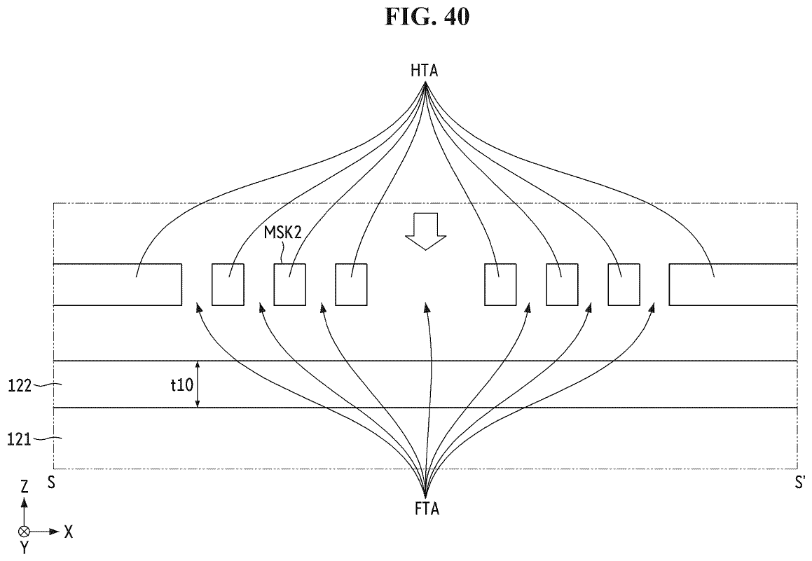

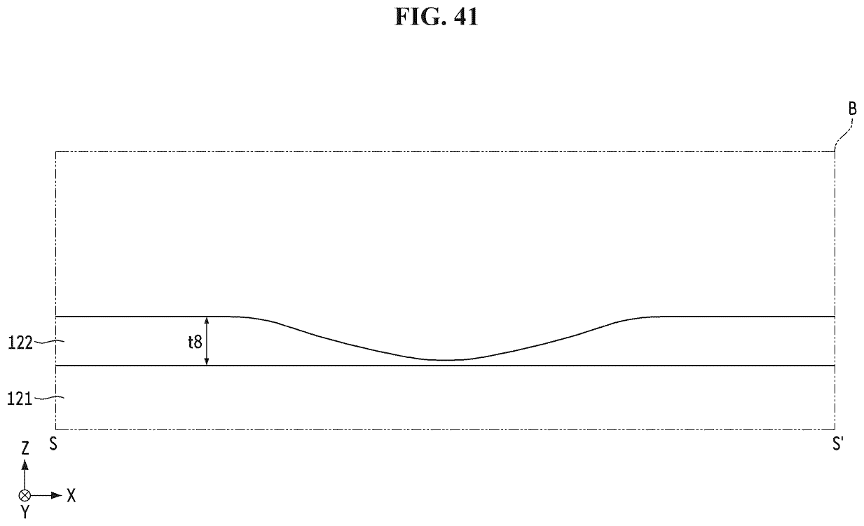

FIG. 39 is a plan view illustrating a slit mask on the second planarization film in the manufacturing method of the display device (or the method of manufacturing the display device) according to one or more embodiments of the present disclosure, and FIGS. 40 and 41 are cross-sectional views illustrating a manufacturing method of a display device (or a method of manufacturing a display device) by utilizing the slit mask of FIG. 39. Any contents that overlap one or more embodiments described herein may not be provided or may be briefly described, and the differences will be mainly or predominantly described.

Referring to FIG. 39, a second mask MSK2 may include a plurality of full-tone areas FTA and a plurality of halftone areas HTA. The plurality of full-tone areas FTA and the plurality of halftone areas HTA may be alternately arranged or provided. In one or more embodiments, in the full-tone areas FTA, 100% of light from an exposure device may pass through to expose the second planarization film 122, and in the halftone areas HTA, only about 50% of the light from the exposure device may pass through to expose the second planarization film 122. In this case, because the second planarization film 122 has fluidity before being cured, an inclination of an inclined surface of an upper surface of the second planarization film 122 may gradually change. The second planarization film 122 may be a positive photoresist.

Referring to FIGS. 40 and 41, a second planarization film 122 having a first application thickness t10 may be formed or provided on the first planarization film 121. Next, an inclined surface of the upper surface of the planarization film 120 may be formed or provided by exposing the second planarization film 122 by utilizing the second mask MSK2 including the plurality of full-tone areas FTA and the plurality of halftone areas HTA, and developing the exposed second planarization film 122. In one or more embodiments, a maximum thickness of the second planarization film 122 after exposure may be the eighth thickness t8, which may be smaller than the first application thickness t10. Next, as described in one or more embodiments, a pixel electrode 131, a pixel defining film 135, a light emitting layer 132, a common electrode 133, and a thin film encapsulation layer 140 may be sequentially formed or provided.

It is illustrated in the drawings that the full-tone areas FTA and the halftone areas HTA may be spaced and/or apart (e.g., spaced apart or separated) by an equal distance (e.g., a substantially equal distance), but embodiments of the present disclosure are not limited thereto. By adjusting a spaced distance between the full-tone areas FTA and the halftone areas HTA, the degree to or occurrence of which the light from the exposure device is irradiated onto the upper surface of the second planarization film 122 may be adjusted.

For example, if (e.g., when) the spaced distance between the full-tone areas FTA is short (e.g., the spaced distance between the halftone areas HTA is long), the amount of light from the exposure device irradiated onto the upper surface of the second planarization film 122 may increase. In contrast, if (e.g., when) the spaced distance between the full-tone areas FTA is long (e.g., the spaced distance between the halftone areas HTA is short), the amount of light from the exposure device irradiated onto the upper surface of the second planarization film 122 may decrease. Through this, the inclination of the inclined surface of the upper surface of the second planarization film 122 and the range of formation of the inclined surface may be adjusted.

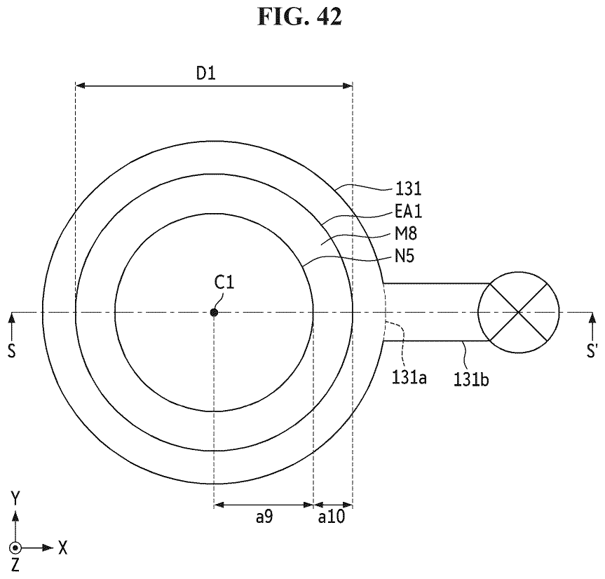

FIG. 42 is an enlarged layout view illustrating another example of the pixel electrode of the first light emitting area EA1 of FIG. 2.

Referring to FIG. 42, the first light emitting area EA1 may include a fifth inclined portion N5 and an eighth flat portion M8.

The fifth inclined portion N5 may be at a central portion of the first light emitting area EA1. The fifth inclined portion N5 may be an area in which a set or predetermined inclination is formed or provided in the pixel electrode 131. Because the inclination is formed or provided in the pixel electrode 131, the fifth inclined portion N5 may be an area in which light generated in the light emitting layer 132 is emitted in a side direction of the display device 10.

A planar shape (e.g., a substantially planar shape) of the fifth inclined portion N5 may follow the planar shape (e.g., the substantially planar shape) of the first light emitting area EA1. If (e.g., when) the first light emitting area EA1 has a circular planar shape (e.g., a substantially circular planar shape) as in FIG. 42, the planar shape (e.g., the substantially planar shape) of the fifth inclined portion N5 may also be circular (e.g., substantially circular). A maximum length a9 of the fifth inclined portion N5 in the first direction (X-axis direction) may be smaller than the maximum length D1 of the first light emitting area EA1 in the first direction (X-axis direction).

The eighth flat portion M8 may be around (e.g., surround) an outer portion of the fifth inclined portion N5. The eighth flat portion M8 may be an area in which the pixel electrode 131 is flat (e.g., substantially flat) or the inclination of the pixel electrode 131 is less than a first angle. For example, the eighth flat portion M8 may be an area in which the pixel electrode 131 is flat or is close to flat (e.g., substantially flat). Accordingly, light generated in the light emitting layer 132 of the eighth flat portion M8 may be emitted in a front direction of the display device 10.

The planar shape (e.g., the substantially planar shape) of the eighth flat portion M8 may have a round ring shape (e.g., a substantially round ring shape) or a round loop shape (e.g., a substantially round loop shape) having a hollow center, like a donut. A width a10 of the eighth flat portion M8 may be smaller than the maximum length D1 of the first light emitting area EA1 in the first direction (X-axis direction). In one or more embodiments, a minimum value of the width a10 of the eighth flat portion M8 may be about 0.5 μm.

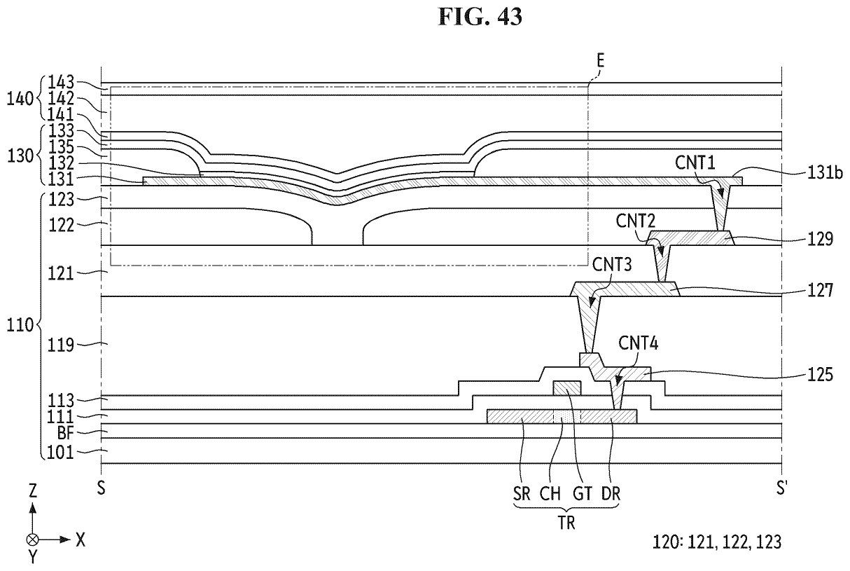

FIG. 43 is a cross-sectional view illustrating a cross section taken along the line S-S′ of FIG. 42.

Referring to FIG. 43, the display panel 100 may include a substrate 101, and a thin film transistor layer 110, a light emitting element layer 130, and a thin film encapsulation layer 140 that are on the substrate 101. Among the components, because the remaining portions except for the planarization film 120 of the thin film transistor layer 110 may be formed or provided in substantially the same manner as described in one or more embodiments, a description thereof may not be provided.

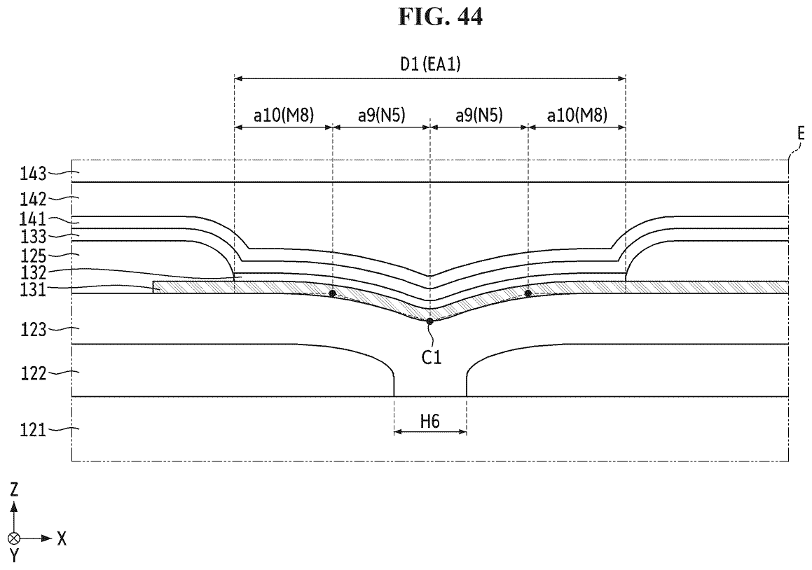

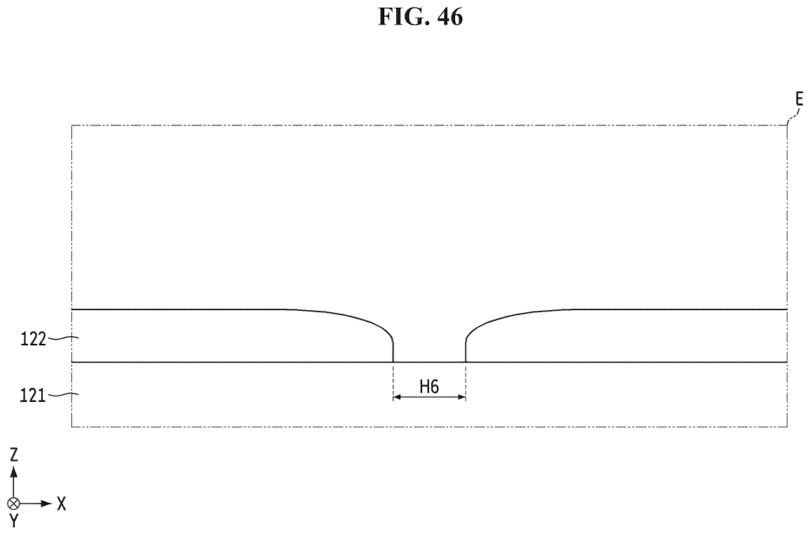

The planarization film 120 may include a first planarization film 121, a second planarization film 122, and a third planarization film 123. In one or more embodiments, the second planarization film 122 may include a sixth hole (H6 in FIG. 46). A more detailed description of the planarization film 120 will be provided herein with reference to FIG. 44.

FIG. 44 is an enlarged cross-sectional view of part E of FIG. 43.

Referring to FIG. 44, in the eighth flat portion M8, an upper surface of the planarization film 120 may be flat (e.g., substantially flat) or an inclination of the upper surface of the planarization film 120 may be less than a first angle. For example, the first angle may be about 3°. If (e.g., when) the inclination of the upper surface of the planarization film 120 is less than about 3°, the upper surface of the planarization film 120 may be seen as almost flat (e.g., substantially flat) without any inclination. The upper surface of the planarization film 120 refers to an upper surface of the third planarization film 123, a portion of an upper surface of the second planarization film 122 that does not overlap the third planarization film 123, and a portion of an upper surface of the first planarization film 121 that does not overlap the second planarization film 122.

In the fifth inclined portion N5, the inclination of the upper surface of the planarization film 120 may be the first angle or more. If (e.g., when) the inclination of the upper surface of the planarization film 120 is about 3° or more, the upper surface of the planarization film 120 may be seen as having a set or predetermined inclination.

The planarization film 120 may include a first planarization film 121, a second planarization film 122, and a third planarization film 123. The first planarization film 121 may be on the protective layer 119. An upper surface of the first planarization film 121 may be formed or provided to be flat (e.g., substantially flat).

The second planarization film 122 may be on the first planarization film 121. The second planarization film 122 may include a sixth hole H6 that penetrates through the second planarization film 122. The sixth hole H6 may overlap the fifth inclined portion N5.

A thickness of the planarization film 120 may increase from a center C1 of the fifth inclined portion N5 to an outer portion of the fifth inclined portion N5.

In one or more embodiments, an area of the inclined surface of the light emitting layer 132 may be increased by forming or providing the inclined surface at the central portion of the light emitting area. Accordingly, the amount of light emitted from the inclined surface of the light emitting layer 132 and directed toward the side of the display device 10 may increase. Therefore, according to the present disclosure, the luminance and color difference for each viewing angle if (e.g., when) observing the display device 10 from the side may be improved or enhanced.

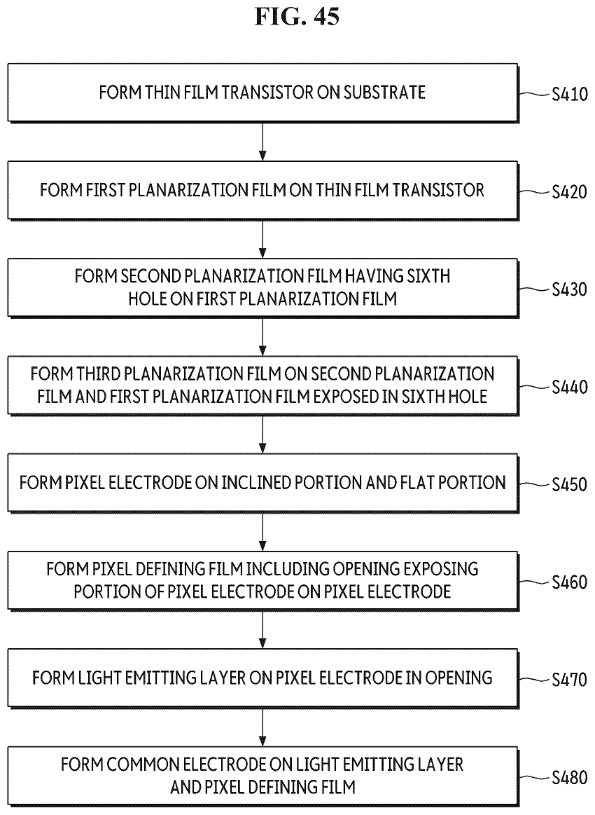

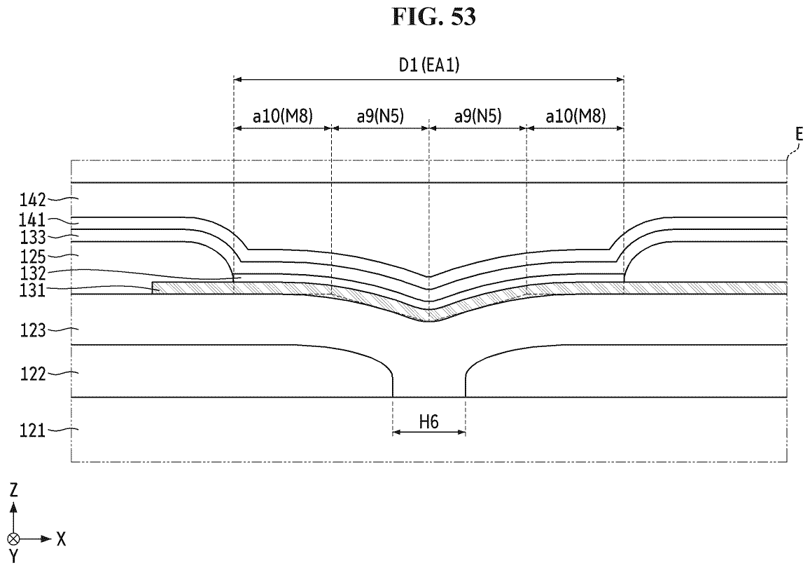

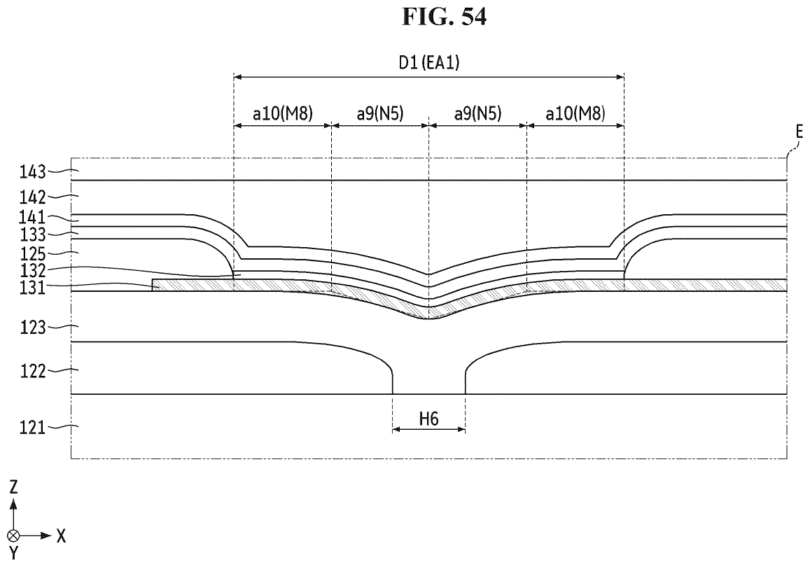

FIG. 45 is a flowchart illustrating a manufacturing method of a display device (or a method of manufacturing a display device) according to one or more embodiments of the present disclosure, and FIGS. 46 to 54 are views illustrating in more detail the manufacturing method of the display device (or the method of manufacturing the display device) of FIG. 45.

Hereinafter, a manufacturing method of a display device (or a method of manufacturing a display device) according to one or more embodiments of the present disclosure will be described in more detail with reference to FIGS. 45 to 54. Any parts that overlap one or more embodiments described herein may not be provided or may be briefly described, and the differences will be mainly or predominantly described.

First, a plurality of thin film transistors TR may be formed or provided on a substrate 101 (S410 in FIG. 45). Next, a first planarization film 121 may be formed or provided on the thin film transistors TR (S420 in FIG. 45). Next, a second planarization film 122 having a sixth hole H6 may be formed or provided on the first planarization film 121 (S430 in FIG. 45).

Referring to FIG. 46, a second planarization film 122 may be formed or provided on the first planarization film 121. The sixth hole H6 may be formed or provided by exposing the second planarization film 122 by utilizing a mask having an opening and developing the exposed second planarization film 122. In one or more embodiments, a maximum length of the sixth hole H6 in the first direction (X-axis direction) may vary depending on the opening of the mask.

In one or more embodiments, because the second planarization film 122 is an organic film, an inclined surface having a continuously (e.g., substantially continuously) changing inclination may be formed or provided around (e.g., surrounding) the sixth hole H6 of the second planarization film 122.

Next, a third planarization film 123 may be formed or provided on the second planarization film 122 and the first planarization film 121 exposed in the sixth hole H6 (S440 in FIG. 45).

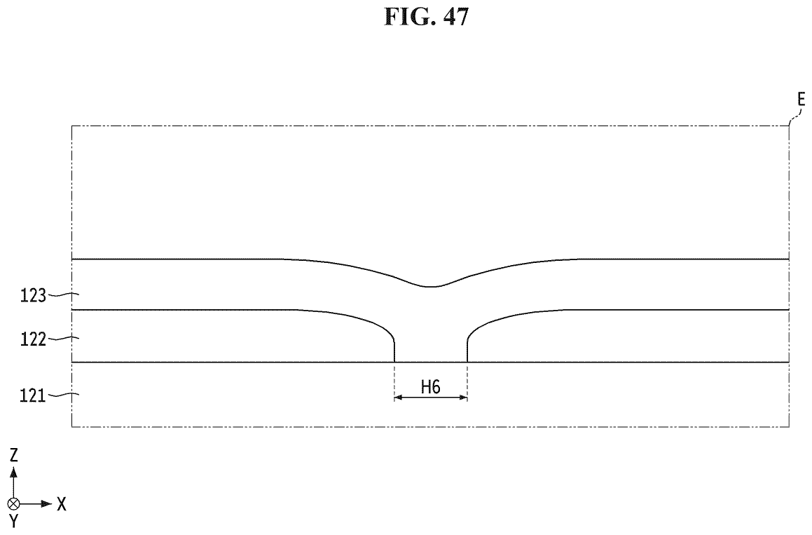

Referring to FIG. 47, the third planarization film 123 may be formed or provided on the second planarization film 122 and the first planarization film 121 exposed in the sixth hole H6. Because the third planarization film 123 is an organic film, an inclined surface having a continuously (e.g., substantially continuously) changing inclination may be formed or provided around (e.g., surrounding) the sixth hole H6.

Next, a pixel electrode 131 may be formed or provided on the inclined portion and the flat portion (S450 in FIG. 45).

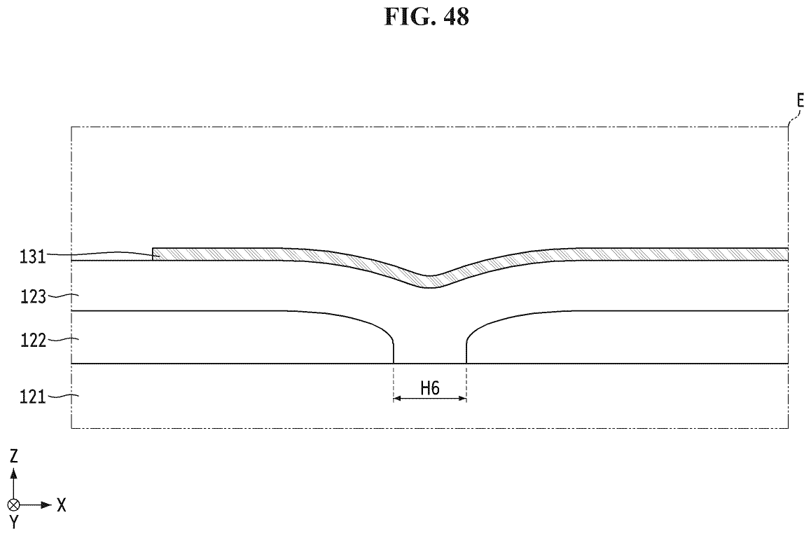

Referring to FIGS. 44 and 48, the pixel electrode 131 may be formed or provided on the fifth inclined portion N5 and the eighth flat portion M8. In this case, one side of the pixel electrode 131 may protrude more than the eighth flat portion M8 as described in FIG. 44, and the other side of the pixel electrode 131 may extend to the first contact hole CNT1 and be electrically connected to the transistor.

Next, a pixel defining film 125 including an opening that exposes a portion of the pixel electrode 131 may be formed or provided on the pixel electrode 131 (S460 in FIG. 45).

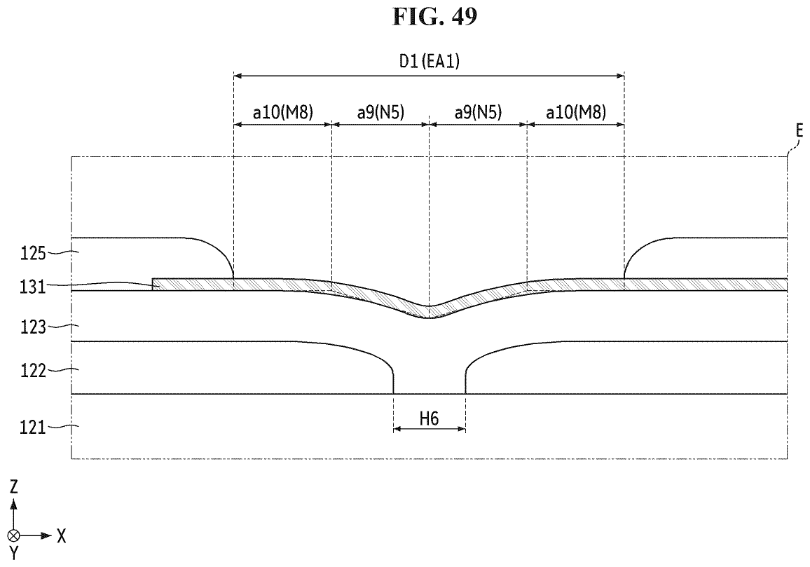

Referring to FIG. 49, a pixel defining film 125 including an opening that exposes a portion of the pixel electrode 131 may be formed or provided on the pixel electrode 131. As the pixel defining film 125 is formed or provided, the eighth flat portion M8 of the third planarization film 123 may be defined with the interior of the opening as a boundary.

Next, a light emitting layer 132 may be formed or provided on the pixel electrode 131 in the opening (S470 in FIG. 45).

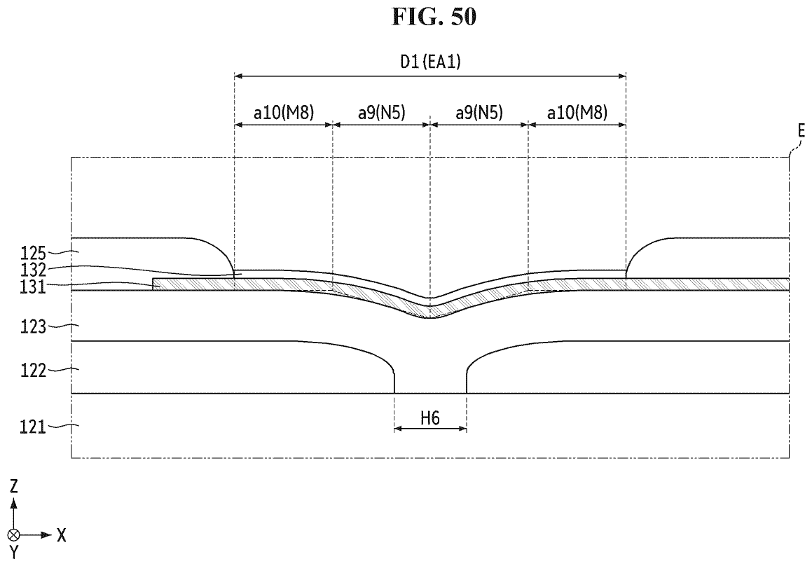

Referring to FIG. 50, a light emitting layer 132 may be formed or provided on the pixel electrode 131 in the opening. The light emitting layer 132 may include a fifth inclined portion N5 and an eighth flat portion M8 so as to correspond to a shape of the pixel electrode 131.

Next, a common electrode 133 may be formed or provided on the light emitting layer 132 and the pixel defining film 125 (S480 in FIG. 45).

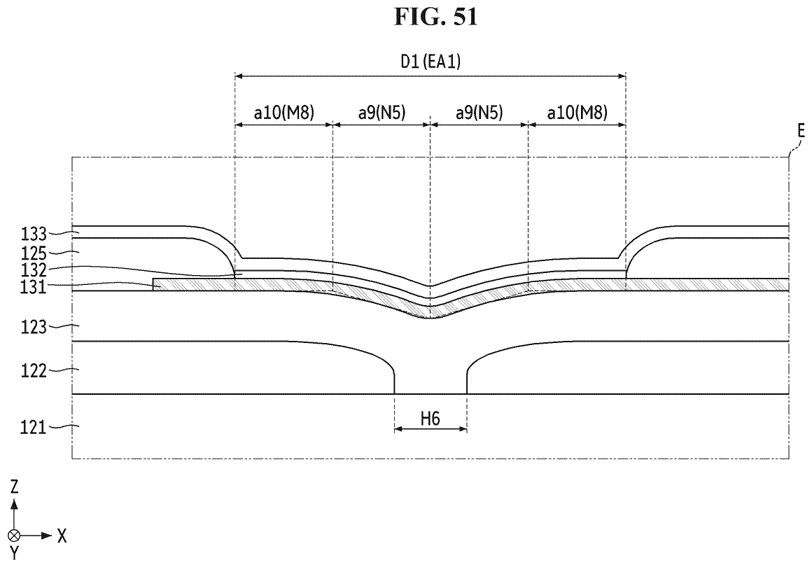

Referring to FIG. 51, a common electrode 133 may be formed or provided on the light emitting layer 132 and the pixel defining film 125. The common electrode 133 may include a fifth inclined portion N5 and an eighth flat portion M8 so as to correspond to a shape of the light emitting layer 132.

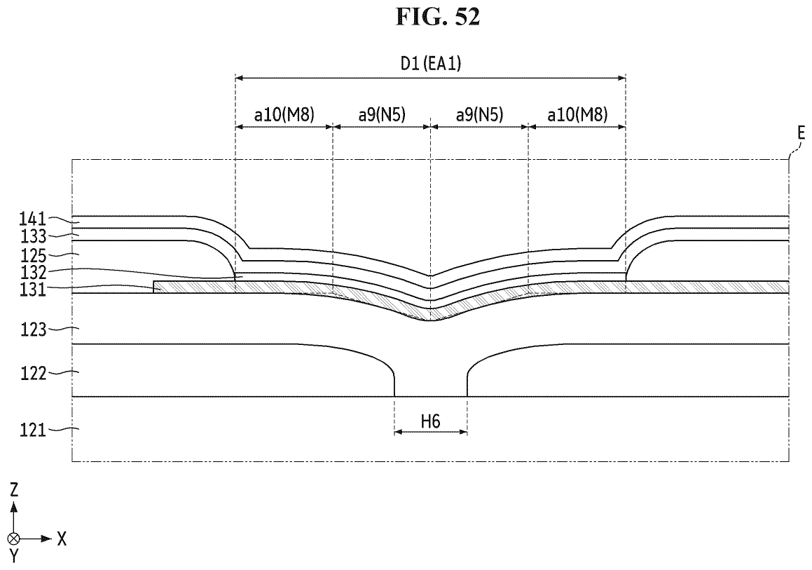

Next, referring to FIGS. 52 to 54, a first inorganic encapsulation layer 141, a first organic encapsulation layer 142, and a second inorganic encapsulation layer 143 may be sequentially formed or provided on the common electrode 133.

The first inorganic encapsulation layer 141 may include a fifth inclined portion N5 and an eighth flat portion M8 so as to correspond to a shape of the common electrode 133. A lower surface of the first organic encapsulation layer 142 may be formed or provided to correspond to a shape of the first inorganic encapsulation layer 141. In one or more embodiments, an upper surface of the first organic encapsulation layer 142 may be formed or provided in a flat shape (e.g., a substantially flat shape). The second inorganic encapsulation layer 143 may be formed or provided in a flat shape (e.g., a substantially flat shape) like the upper surface of the first organic encapsulation layer 142.

A person of ordinary skill in the art would appreciate, in view of the present disclosure in its entirety, that each suitable feature of the one or more embodiments of the present disclosure may be combined or combined with each other, partially or entirely, and may be technically interlocked and operated in one or more suitable ways, and each embodiment may be implemented independently of each other or in conjunction with each other in any suitable manner unless otherwise stated or implied.

It will be understood by one of ordinary skill in the art to which the present disclosure belongs that the present disclosure may be implemented in one or more suitable forms without changing the spirit and scope of the present disclosure. Therefore, it will be understood that the one or more embodiments as described in the present disclosure are illustrative rather than being restrictive in all aspects. It will be understood that the scope of the present disclosure are defined by the scope of the appended claims and equivalents thereof rather than the detailed description as described above and all modifications and alterations derived from the appended claims and their equivalents fall within the scope of the present disclosure.

What is claimed is:

1. A display device comprising:
a substrate;
a thin film transistor layer on one surface of the substrate;
a planarization film on the thin film transistor and comprising a first flat portion and a second flat portion that are spaced from each other and a first inclined portion between the first flat portion and the second flat portion;
a pixel electrode on the first flat portion, the first inclined portion, and the second flat portion of the planarization film;
a pixel defining film comprising an opening exposing a portion of the pixel electrode;
a light emitting layer on the pixel electrode in the opening; and
a common electrode on the light emitting layer and the pixel defining film,
wherein a minimum thickness of the planarization film in the first flat portion is smaller than a minimum thickness of the planarization film in the second flat portion, and
a thickness of the planarization film in the first inclined portion decreases from the second flat portion to the first flat portion.

2. The display device as claimed in claim 1, wherein an extension line of an upper surface of the planarization film extending parallel to one surface of the substrate in the first flat portion is defined as a first extension line,
an extension line of the upper surface of the planarization film extending parallel to one surface of the substrate in the second flat portion is defined as a second
a line connecting a first point where the first inclined portion and the first extension line cross and a second point where the first inclined portion and the second extension line cross is defined as a first inclination line, and
an angle between the first extension line and the first inclination line is about 15° to about 35°.

3. The display device as claimed in claim 2, wherein a maximum length between one end of the second flat portion and the second point is about 0.5 μm to about 1.5 μm.

4. The display device as claimed in claim 1, wherein a planar area of the first inclined portion is about 70% to about 80% of a planar area of the opening.

5. The display device as claimed in claim 1, wherein the planarization film further comprises:
a second inclined portion spaced from the first inclined portion; and
a third flat portion spaced from the second flat portion, and
wherein the second inclined portion is between the second flat portion and the third flat portion.

6. The display device as claimed in claim 5, wherein an extension line of an upper surface of the planarization film extending parallel to one surface of the substrate in the first flat portion is defined as a first extension line,
an extension line of the upper surface of the planarization film extending parallel to one surface of the substrate in the second flat portion is defined as a second
an extension line of the upper surface of the planarization film extending parallel to one surface of the substrate in the third flat portion is defined as a third extension line,
a line connecting a first point where the first inclined portion and the first extension line cross and a second point where the second inclined portion and the second extension line cross is defined as a first inclination line,
a line connecting the second point and a third point where the second inclined portion and the third extension line cross is defined as a second inclination line, and
a first angle, which is an acute angle between the first extension line and the first inclination line, is greater than a second angle, which is an acute angle between the second extension line and the second inclination line.

7. The display device as claimed in claim 5, wherein a maximum length of the first flat portion in a first direction is about 20% to about 40% of a maximum length of the opening in the first direction.

8. The display device as claimed in claim 7, wherein an area of the first inclined portion is about 10% to about 45% of a planar area of the opening.

9. The display device as claimed in claim 8, wherein a thickness of the first inclined portion is about 1.0 μm to about 2.5 μm.

10. The display device as claimed in claim 7, wherein a planar area of the second flat portion is about 10% to about 25% of a planar area of the opening.

11. The display device as claimed in claim 10, wherein a thickness of the second inclined portion is about 0.4 μm to about 1.5 μm.

12. The display device as claimed in claim 5, wherein the pixel electrode comprises:
a first hole defined by a boundary between the first flat portion and the first inclined portion; and
a second hole defined by a boundary between the second flat portion and the second inclined portion.

13. The display device as claimed in claim 12, wherein a size of the second hole is greater than a size of the first hole, and a size of the opening is greater than the size of the second hole.

14. The display device as claimed in claim 12, wherein the first hole and the second hole overlap the opening.

15. A display device comprising:
a substrate;
a thin film transistor layer on one surface of the substrate;
a planarization film on the thin film transistor and comprising an inclined portion and a flat portion;
a pixel electrode on the inclined portion and the flat portion of the planarization film;
a pixel defining film comprising an opening exposing a portion of the pixel electrode;
a light emitting layer on the pixel electrode in the opening; and
a common electrode on the light emitting layer and the pixel defining film,
wherein the inclined portion overlaps a central portion of the pixel electrode, and
the flat portion is around the inclined portion.

16. The display device as claimed in claim 15, wherein a thickness of the planarization film increases from a central portion of the inclined portion to an outer portion of the inclined portion.

17. The display device as claimed in claim 15, wherein a width of the flat portion in a first direction is about 0.5 μm to about 1.5 μm.

18. An electronic device comprising a display device, the display device comprising:
a substrate;
a thin film transistor layer on one surface of the substrate;
a planarization film on the thin film transistor and comprising a first flat portion and a second flat portion that are spaced from each other and a first inclined portion between the first flat portion and the second flat portion;
a pixel electrode on the first flat portion, the first inclined portion, and the second flat portion of the planarization film;
a pixel defining film comprising an opening exposing a portion of the pixel electrode;
a light emitting layer on the pixel electrode in the opening; and
a common electrode on the light emitting layer and the pixel defining film,
wherein a minimum thickness of the planarization film in the first flat portion is smaller than a minimum thickness of the planarization film in the second flat portion, and
a thickness of the planarization film in the first inclined portion decreases from the second flat portion to the first flat portion.
